(19) United States
(12) Patent Application Publication
(10) Pub. No.: US 2020/0152502 A1
(43) Pub. Date: May 14, 2020

(54) METHODS AND APPARATUS FOR A THREE-DIMENSIONAL (3D) ARRAY HAVING ALIGNED DEEP-TRENCH CONTACTS

(71) Applicant: NEO Semiconductor, Inc., San Jose, CA (US)

(72) Inventor: Fu-Chang Hsu, San Jose, CA (US)

(21) Appl. No.: 16/674,906

(22) Filed: Nov. 5, 2019

Related U.S. Application Data
(60) Provisional application No. 62/757,747, filed on Nov. 8, 2018.
(60) Provisional application No. 62/777,060, filed on Dec. 7, 2018.
(60) Provisional application No. 62/800,404, filed on Feb. 1, 2019.
(60) Provisional application No. 62/800,480, filed on Feb. 2, 2019.
(60) Provisional application No. 62/807,169, filed on Feb. 18, 2019.
(60) Provisional application No. 62/837,180, filed on Apr. 22, 2019.

(51) Int. Cl. H01L 21/74; H01L 23/535; H01L 21/3213; H01L 21/311

(52) U.S. Cl. CPC H01L 21/743; H01L 21/31144; H01L 21/32139; H01L 23/535

(57) ABSTRACT

Methods and apparatus for a three-dimensional (3D) array having aligned deep-trench contacts are disclosed. In an embodiment, a method includes forming an array stack having conductor layers and insulator layers, and forming a hard mask on top of the array stack. The hard mask includes a plurality of holes. The method also includes forming a pull-back mask on top of the hard mask, and etching the pull-back mask so that at least one hole of the hard mask is exposed. The method also includes etching through one or more exposed holes of the hard mask to remove one or more layers of the array stack.

### CROSS-REFERENCE TO RELATED APPLICATIONS

This application claims the benefit under 35 U.S.C. § 119 of U.S. Provisional Patent Application No. 62/757,747, filed on Nov. 8, 2018, and entitled “3D Array Conductor Layer's Connection,” and U.S. Provisional Patent Application No. 62/777,060, filed on Dec. 7, 2018, and entitled “3D Array Conductor Layer's Connection,” and U.S. Provisional Patent Application No. 62/800,404, filed on Feb. 1, 2019, and entitled “3D Array Conductor Layer's Connection,” and U.S. Provisional Patent Application No. 62/800,480, filed on Feb. 2, 2019, and entitled “3D Array Conductor Layer's Connection,” and U.S. Provisional Patent Application No. 62/807,169, filed on Feb. 18, 2019, and entitled “3D Array Conductor Layer's Connection,” and U.S. Provisional Patent Application No. 62/837,180, filed on Apr. 22, 2019, and entitled “3D Array Conductor Layer's Connection,” all of which are hereby incorporated herein by reference in their entireties.

### FIELD OF THE INVENTION

The exemplary embodiments of the present invention relate generally to the field of semiconductors and integrated circuits, and more specifically to three-dimensional semiconductor arrays.

### BACKGROUND OF THE INVENTION

A three-dimensional (3D) array contains multiple conductor layers, such as word line (WL) layers or bit line (BL) layers running in a horizontal direction and that are separated by insulating layers. These conductor layers are connected to signal lines through vertical contact holes that run through the array. In a conventional process, the multiple layers of the array are etched into a ‘staircase’ and then connected by deep-trenched contacts to metal lines on top of the array. Unfortunately, because the height of a 3D array is typically about 2 to 3 micrometers (um), the deep-trench contacts may cause significant misalignment issues and reduce yield. To overcome misalignment problems, the etched staircase must be very wide, such as 1 um for each stair step. As the array becomes larger, the size penalty for the staircase increases. Furthermore, because the stairs are typically etched using multiple etching steps, if the alignment of one stair step is off by a few percent that error will propagate to subsequent stair steps.

### SUMMARY

In various exemplary embodiments, methods and apparatus are provided for forming 3D arrays with precisely aligned deep-trench contacts. For example, the embodiments are suitable for use with 3D arrays, such as 3D NAND flash memory, 3D resistive random-access memory (RRAM), 3D phase-change memory (PCM), 3D ferroelectric random-access memory (FRAM), 3D magnetoresistive random-access memory (MRAM), 3D neural network, and many other 3D arrays.

In an embodiment, an array stack having conductor layers and insulating layers is formed. A hard mask with precise hole shapes and locations is formed on the array stack. A second mask is formed on the hard mask. The second mask is “pull-back” etched to expose one or more holes in the hard mask. One or more layers within the exposed holes are etched away to extend the depth of those holes in the array stack. The second mask is “pull-back” etched again to expose additional holes in the hard mask. The insulator and/or conductor layer etching process is performed again within any of the exposed holes of the hard mask to extend the depth of those holes in the array stack. The pull-back etch of the second mask and the insulator/conductor etching process are repeatedly performed until all the contact holes in the hard mask have a desired depth in the array stack. The result of the above operations is a 3D array with precisely aligned contact holes. Conductor material is then deposited within the contact holes to provide a conduction path from each of the conductor layers to the top of the array stack.

In an embodiment, a method includes forming an array stack having conductor layers and insulator layers, and forming a hard mask on top of the array stack. The hard mask includes a plurality of holes. The method also includes forming a pull-back mask on top of the hard mask, and etching the pull-back mask so that at least one hole of the hard mask is exposed. The method also includes etching through one or more exposed holes of the hard mask to remove one or more layers of the array stack.

In an embodiment, a three-dimensional (3D) array is formed by performing operations that include forming an array stack having conductor layers and insulator layers, forming a hard mask on top of the array stack. The hard mask includes a plurality of holes. Forming the 3D array also includes forming a pull-back mask on top of the hard mask, and etching the pull-back mask so that the at least one hole of the hard mask is exposed. Forming the 3D array also includes etching through one or more exposed holes of the hard mask to remove one or more layers of the array stack.

Additional features and benefits of the present invention will become apparent from the detailed description, figures and claims set forth below.

### BRIEF DESCRIPTION OF THE DRAWINGS

The exemplary embodiments of the present invention will be understood more fully from the detailed description given below and from the accompanying drawings of various embodiments of the invention, which, however, should not be taken to limit the invention to the specific embodiments, but are for explanation and understanding only.

FIGS. 1-2O show exemplary processing operations to form a 3D array stack having aligned deep-trench vertical contacts.

FIGS. 3A-M show exemplary processing operations to form a 3D array stack having aligned deep-trench vertical contacts.

FIGS. 4A-H show exemplary processing operations to form a 3D array stack having aligned deep-trench vertical contacts.

FIGS. 5A-D show exemplary processing operations to form a 3D array stack having deep-trench vertical contacts with reduced misalignment.

FIGS. 6A-B show exemplary processing operations to form a 3D array stack having deep-trench vertical contacts with reduced misalignment and that utilize square contact holes.

FIGS. 7A-F show exemplary processing operations to form a 3D array stack having deep-trench vertical contacts with reduced misalignment and that utilize staircase etching processes to form word line contacts.

FIGS. 8A-D show exemplary processing operations to form a 3D array stack having deep-trench vertical contacts with reduced misalignment and that utilize etch stop layers and staircase etching processes to form word line contacts.

FIGS. 9A-H show exemplary processing operations to form a 3D array stack having deep-trench vertical contacts with reduced misalignment and that utilize line pattern hard masks.

FIGS. 10A-F show exemplary processing operations to form a 3D array stack having deep-trench vertical contacts with reduced misalignment and that utilizes line pattern hard masks.

FIGS. 11A-D show exemplary processing operations to form a 3D array stack having deep-trench vertical contacts with reduced misalignment and that connect with circuitry under the array.

FIGS. 12A-B show exemplary processing operations to form a 3D array stack having deep-trench vertical contacts with reduced misalignment and that connect with circuitry under the array.

FIGS. 13-14 show exemplary processing operations to form a 3D array stack having deep-trench vertical contacts with reduced misalignment and that connect with circuitry under the array.

### DETAILED DESCRIPTION

Exemplary embodiments of the present invention are described herein in the context of processes, devices, methods, and apparatus for providing 3D arrays having aligned deep trench contacts.

Those of ordinary skilled in the art will realize that the following detailed description is illustrative only and is not intended to be in any way limiting. Other embodiments of the present invention will readily suggest themselves to such skilled persons having the benefit of this disclosure. Reference will now be made in detail to implementations of the exemplary embodiments of the present invention as illustrated in the accompanying drawings. The same reference indicators (or numbers) will be used throughout the drawings and the following detailed description to refer to the same or like parts.

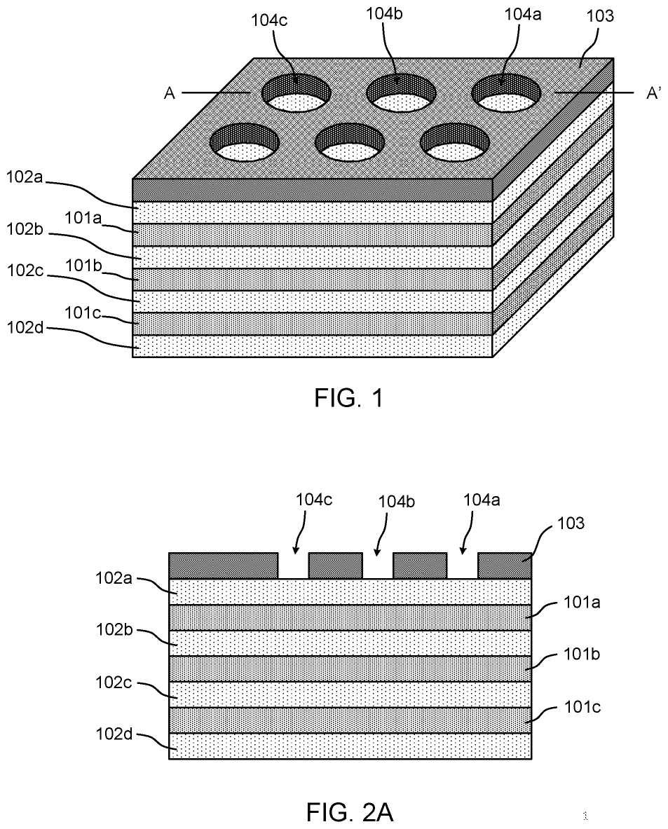

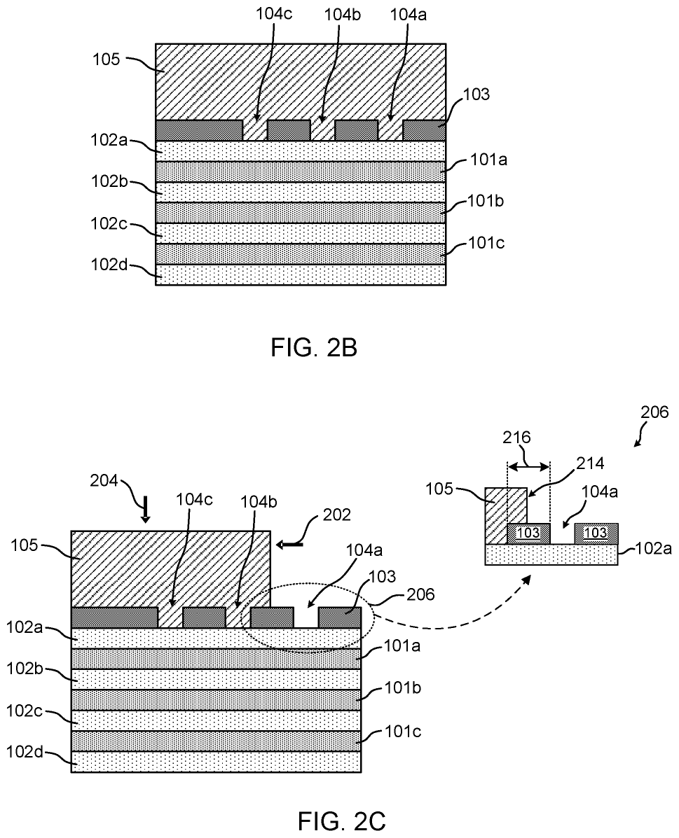

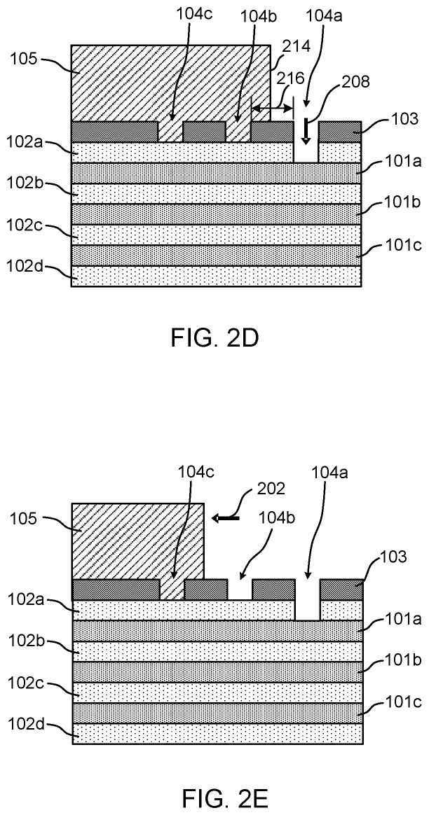

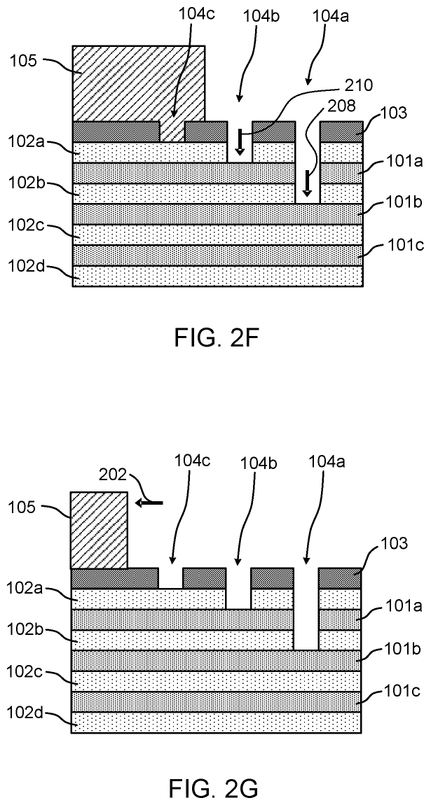

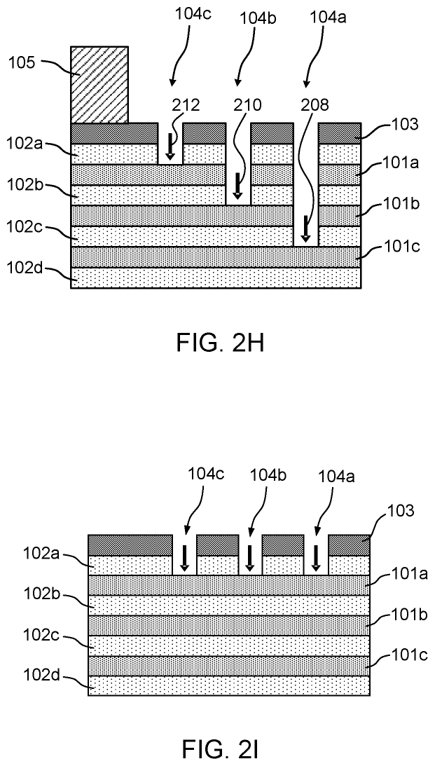

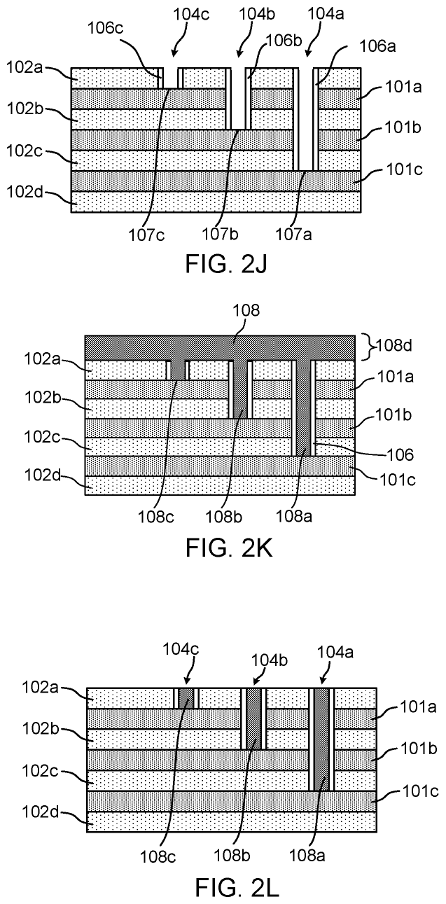

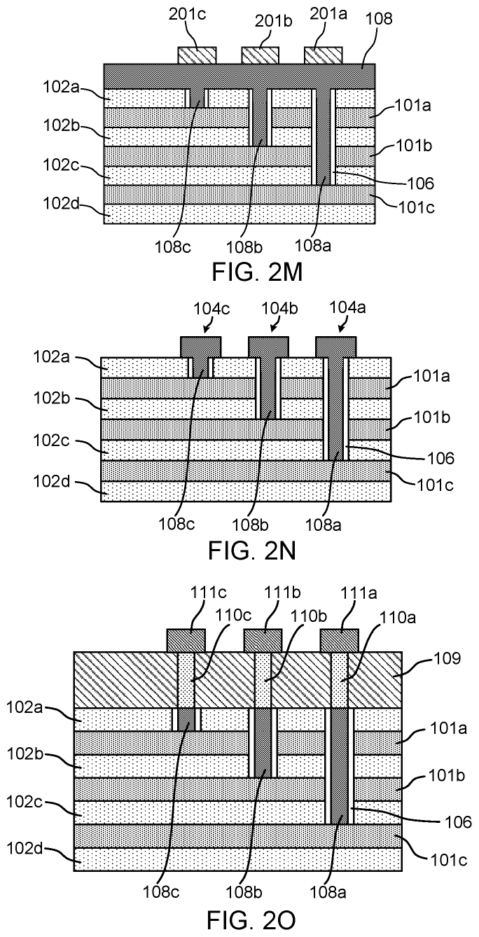

FIGS. 1-2O show exemplary processing operations to form a 3D array stack having aligned deep-trench vertical contacts.

FIG. 1 shows a 3D array stack constructed in accordance with embodiments of the invention. As illustrated in FIG. 1, multiple conductor layers, such as layers 101a to 101c, and multiple insulating layers, such as layers 102a to 102d, are alternately deposited to form the array stack. A hard mask 103 is formed on top of the stack. In an embodiment, the mask 103 is lithographically defined and etched to form a pattern of contact holes (or openings), such as holes 104a-c. The hard mask 103 may have a selectivity for etching solutions that is different from the etching solution selectivity of the conductor layers 101a-c and the insulating layers 102a-d. In various embodiments, the contact holes may have any shape, such as circular, square, rectangular, triangular, hexagonal, and/or any other shapes. The openings also may be located anywhere on the mask in any desired pattern. FIG. 1 also includes cross-section indicator A-A′.

FIG. 2A shows a cross-section view of the 3D stack shown in FIG. 1. For example, the cross-section view is taken along the cross-section indicator A-A′ shown in FIG. 1. As illustrated in FIG. 2A, the hard mask 103 comprises contact holes 104a-c. The alternating conductor layers 101a-c and the insulating layers 102a-d are also shown in FIG. 2A.

FIG. 2B shows the cross-section view of the 3D stack shown in FIG. 2A. As illustrated in FIG. 2B, a second hard mask 105 is formed on top of the first hard mask 103. For example, the second hard mask 103 comprises a nitride material. The second hard mask 105 has a selectivity for etching solutions that is different from the first hard mask 103. Thus, certain etching solutions may etch the second hard mask 105 without etching the first hard mask 103. Moreover, the second mask 105 has a selectivity for etching solutions that is different from the conductor layers 101a-c and the insulating layers 102a-d. To distinguish the two masks, the first mask 103 is also referred to as a ‘contact hole mask’, and the second mask 105 is also referred to as a ‘pull-back mask’. In an embodiment, the second mask 105 is much thicker than the first mask 103.

FIG. 2C shows the cross-section view of the array stack shown in FIG. 2B. As illustrated in FIG. 2C, the second hard mask 105 is etched to expose the first contact hole 104a of the first mask 103. In an exemplary embodiment, the second mask 105 is etched by using a ‘pull-back’ etching process so that the second mask 105 is etched or “pulled-back” in the direction 202. During the pull-back etching process an isotropic etch is directly applied to the mask 105 without using lithography patterning. Therefore, this type of etching reduces the lithography process steps. This may significantly reduce the process time and costs to form the final array. However, since this direct etching process may also remove a portion of the top of the mask 105 in the direction 204, a very thick mask 105 may be used to allow multiple pull-back etching operations. It should also be noted that the etching material that etches the mask 105 does not etch the mask 103.

### Hard Mask Defines Precise Size and Location for Contact Holes

As illustrated in the exploded view 206, the hard mask 103 defines the precise size and location for the contact holes to be etched through the array layers. For example, the pull-back etching process removes a portion of the mask 105 to expose the hole 104a. The edge 214 of the mask 105 can be pull-back anywhere within the range 216 to expose the hole 104a, which is defined by the hard mask 103. Thus, a precise pull-back etching is not required because the hard mask 103 precisely defines the size and location of the hole 104a. The pull-back mask 105 exposes the contact hole in the hard mask 103 but does not have to be precisely etched to perform this task. The pull-back etch 105 need only have a front edge 214 that is within the range 216.

FIG. 2D shows the cross-section view of the array stack shown in FIG. 2C. As illustrated in FIG. 2D, the depth of the first contact hole 104a is extended by etching away the first insulating layer 102a in the direction 208 through the opening 104a in the hard mask 103. Since the hard mask 103 provides the precise size and location of the region of the insulating layer 102a within the hole 104a to be etched, the front edge 214 of the mask 105 need only be pull-back etched within the range 216 and therefore a precise etching of the pull-back mask 105 is not required. In an embodiment, an anisotropic dry etching process is used to etch the layer 102a in the direction 208. It should be noted that the etching material used to etch the layer 102a does not etch the hard mask 103.

FIG. 2E shows the cross-section view of the array stack shown in FIG. 2D. As illustrated in FIG. 2E, the pull-back mask 105 is pull-back etched or pattern-etched again in the direction 202 to expose the second contact hole 104b on the hard mask 103. It should be noted that the layer 102a within the first contact hole 104a has been etched away in the previous operation described with reference to FIG. 2D. As before, since the hard mask 103 provides the precise size and location of the region of the insulating layer 102a to be etched within the hole 104b, such that the pull-back etching of the mask 105 need not be precise.

FIG. 2F shows the cross-section view of the array stack shown in FIG. 2D. As illustrated in FIG. 2F, a conductor layer etch process and an insulating layer etch process are performed. For example, a conductor layer etch is performed in the opening 104a, in the direction 208, to etch away the conductor layer 101a. Next, the insulating layer etch process is performed in the openings 104a and 104b, in the directions 208 and 210 to etch away the insulating layers 102a and 102b in the openings 104b and 104a, respectively. After the above processes are performed, the contact opening 104a is deep enough to reach the conductor layer 101b, and the contact opening 104b is deep enough to reach the conductor layer 101a. It should be noted that the etching material that is used does not etch the hard mask 103. It should also be noted that the conductor and insulator layers are precisely etched due to the precise location of the holes 104a and 104b in the hard mask 103.

FIG. 2G shows the cross-section view of the array stack shown in FIG. 2F. As illustrated in FIG. 2G, the pull-back mask 105 is pull-back etched or pattern-etched again in the direction 202 to expose the third contact hole (or opening) 104c in the hard mask 103. As before, since the hard mask 103 provides the precise size and location of the region of the insulating layer 102a to be etched within the hole 104c, the pull-back etching of the mask 105 need not be precise. It should be noted that in the previous operations described with reference to FIG. 2F, the layer 102a within the contact hole 104b has been etched away and the layers 101a and 102b within the contact hole 104a have been etched away.

FIG. 2H shows the cross-section view of the array stack shown in FIG. 2G. As illustrated in FIG. 2H, a conductor layer etch process and an insulating layer etch process are performed. For example, a conductor layer etch is performed in the opening 104a, in the direction 208, to etch away the conductor layer 101b. A conductor layer etch also is performed in the opening 104b, in the direction 210, to etch away the conductor layer 101a in the opening 104b. Next, the insulating layer etch process is performed in the openings 104a, 104b, and 104c in the directions 208, 210, 212 to etch away the insulating layers 102a, 102b, and 102c, respectively. After the above processes are performed, the contact opening 104a is deep enough to reach the conductor layer 101c, the contact opening 104b is deep enough to reach the conductor layer 101b, and the contact opening 104c is deep enough to reach the conductor layer 101a. The above processes can be summarized as follows.
1. An array stack having conductor layers and insulating layers is formed
2. A hard mask 103 with precise hole shapes and locations is formed on the array stack.
3. A second mask 105 is formed on the hard mask.
3. The second mask 105 is “pull-back” etched to expose one or more holes in the hard mask 103.
4. One or more layers within the exposed holes are etched away. For example, an insulator etching process and/or a conductor etching process are used to etch away one or more layers within an exposed hole in the hard mask 103 to extend the depth of the holes in the array stack.
5. The second mask 105 is “pull-back” etched again to expose one or more additional holes in the hard mask 103.
6. The insulator and/or conductor etching process is performed within one or more of the exposed holes to extend the depth of the exposed contact holes in the array stack.
7. The pull-back etch of the second mask 105 and the insulator/conductor etch are repeatedly performed until the desired depths of all the contact holes in the array are reached.

Accordingly, the pull-back mask 105 is repeatedly pull-back etched to reveal one or more contact holes on the hard mask 103. One or more insulating layers and/or conductor layers are etched and the process is repeated until the desired depths for all the contact holes in the array are reached. Although the described embodiments uses three conductor layers as example, if the stack has more conductor layers and insulating layers, the above described process steps may be repeated to form contact holes that reach all the conductor layers.

FIG. 2I shows an alternative embodiment for achieving the result of the process steps shown in FIGS. 2A-H. As illustrated in FIG. 2I, after the process step shown in FIG. 2A, the top insulating layer 102a may be etched by using the hard mask 103 to form the array structure shown in FIG. 2I. Next, the pull-back mask 105 is formed on top of the hard mask 103, and the pull-back etch process steps shown in FIGS. 2B-2F are performed. In this embodiment, each step will etch one conductor layer and one insulating layer until the desired hold depth of each hole is reached.

FIG. 2J shows the cross-section view of the array stack shown in FIG. 2H. FIG. 2J illustrates that the remaining materials of the masks 105 and 103 are removed. Insulating layers, such as layers 106a-c are formed on the inside walls of the contact holes 104a-c. Next, the insulating layer that is formed at the bottom of the contact holes 104a-c, such as indicated at bottom surfaces 107a-c, is removed by an anisotropic vertical etch process so that the conductor layers are exposed at the bottom of the contact holes 104a-c.

FIG. 2K shows the cross-section view of the array stack shown in FIG. 2J. As illustrated in FIG. 2K, contact material layer 108 is deposited to fill the contact holes 108a-c and form a top layer 108d to cover the insulating layer 102a. Then, the top layer 108d can be removed by using an etching process without a mask. This will form the individual contacts 108a-c as shown in FIG. 2L.

FIG. 2L shows the cross-section view of the array stack shown in FIG. 2K after the layer 108d is removed. As illustrated in FIG. 2L, the contact holes 104a-c are filled with conductor material 108a-c, such as metal, to form contacts that extend from the conductor layers to the top surface of the array stack. Next, a pull-back etch may be performed to remove the insulating layer 102a on top of the stack to expose the contacts formed by the conductor material 108a-c.

FIG. 2M shows the cross-section view of the array stack shown in FIG. 2K and illustrates another embodiment for providing contacts to the conductor layers. After depositing the contact material 108 as illustrated in FIG. 2K, instead of using an ‘etch-back’ process to remove the top layer 108d, a standard ‘pattern-etch’ process is used to form individual contacts. In this embodiment, a mask layer is deposited and then pattern-etched to form masks 201a-c. Next, an etch process is performed to etch the contact material layer 108. Lastly, the masks 201a-c are removed to result in the contact patterns shown in FIG. 2N.

FIG. 2N shows the cross-section view of the array stack shown in FIG. 2M and illustrates the contact pattern that results after a pattern-etch is performed to separate the conductor layer 108 for each of the contact holes.

FIG. 2O shows the cross-section view of the array stack shown in FIG. 2L and shows another exemplary embodiment for connecting to the metal contacts 108a-c. In this embodiment, an insulating layer 109, such as oxide is formed on top of the stack. Next, holes or vias are formed and filled with conductive material 110a-c to connect the contacts 108a-c to the conductors 111a-c on top of the stack. The conductors 111a-c may be metal or other conductive material that can be connected to other electronics, such as decoder circuits.

In various exemplary embodiments, the contact holes for 3D array's multiple conductor layers are formed without using a staircase etch, and therefore, the misalignment problems of the conventional process are eliminated. This results in smaller contact pitch, smaller size, and higher yields. Moreover, the contact holes are formed by using a hard mask and a pull-back etching process, which significantly reduces the lithography steps and process cost.

It should be noted that although the embodiments shown in FIGS. 1-2O show that the top layer of the stack is an insulating layer (e.g., 102a), in other embodiments, the top layer may be a conductor layer. The operations described herein remain the same, except that some minor changes, such as the order of etching may be modified. For simplicity, the embodiments having a top layer conductor will not be described here, however, it shall remain in the scope of the embodiments.

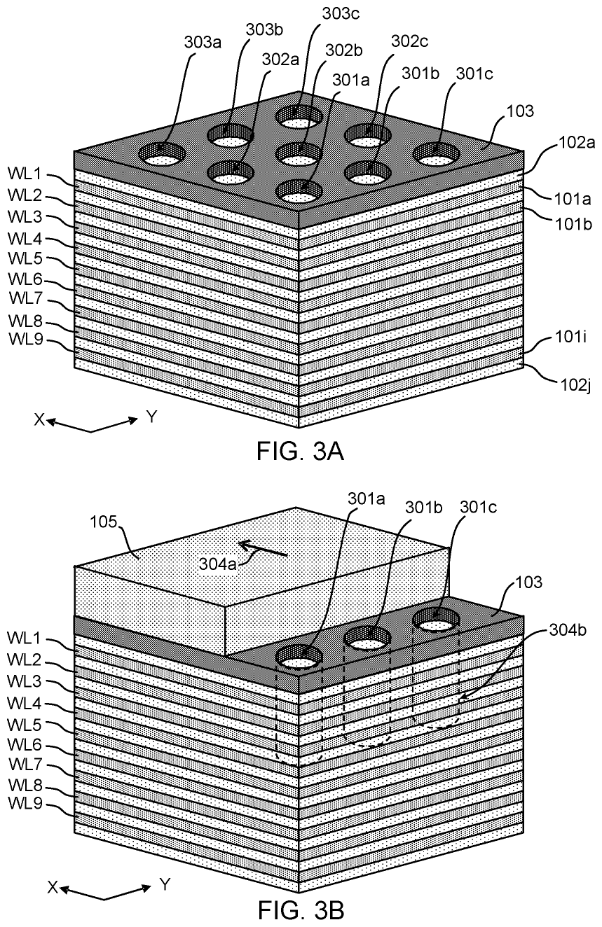

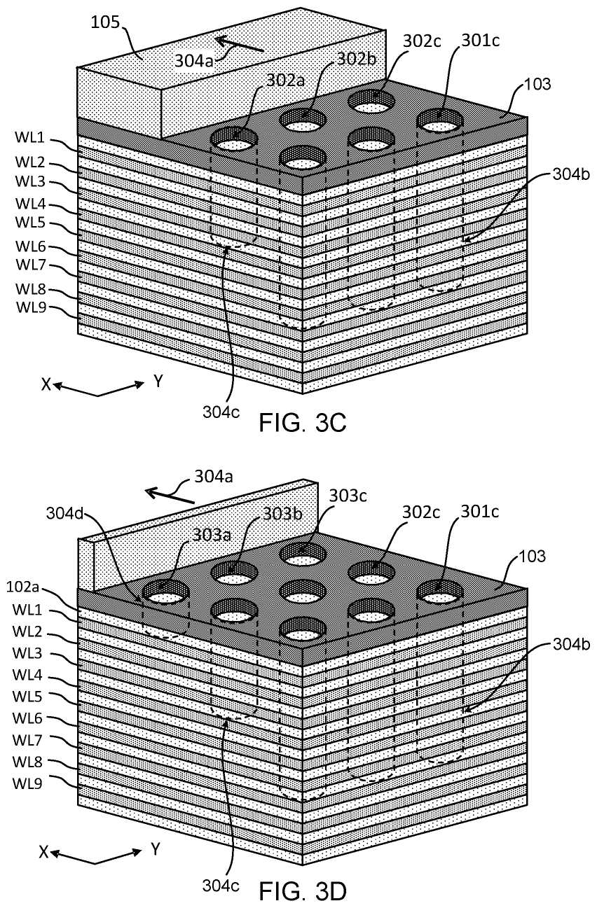

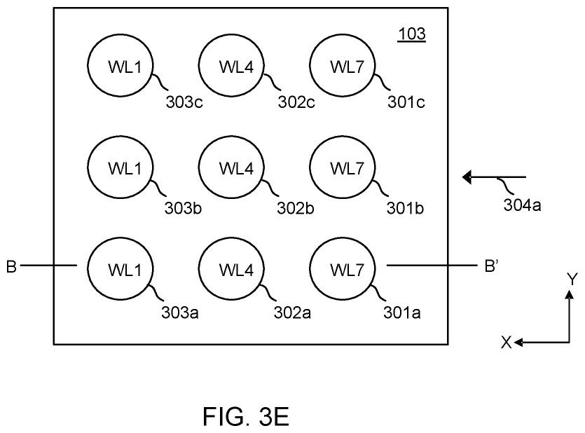

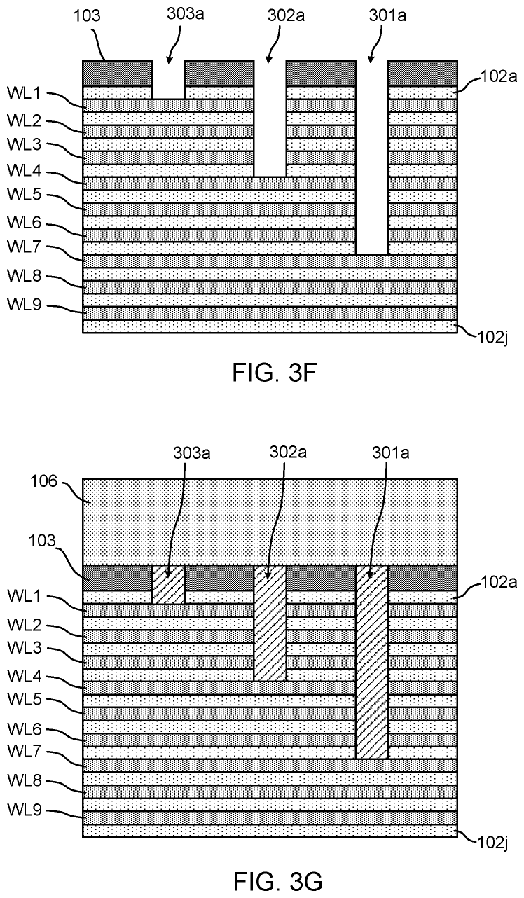

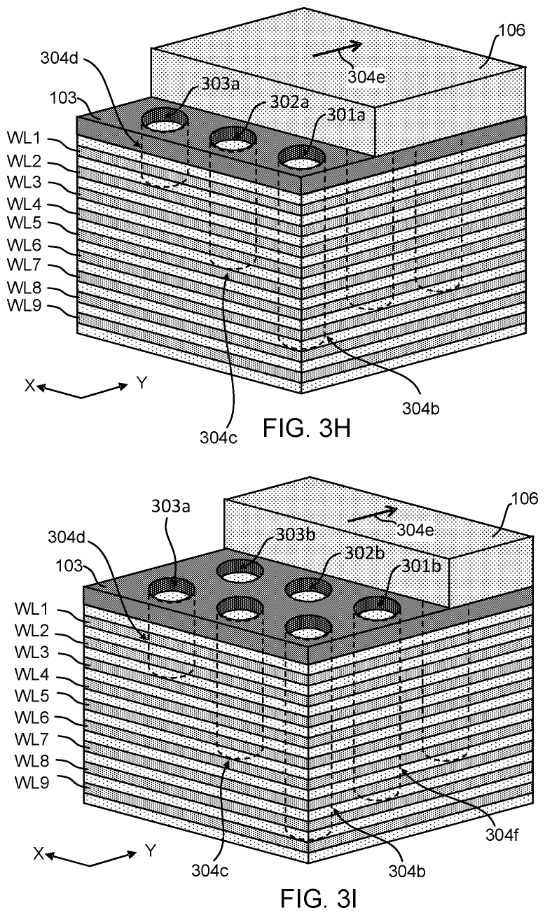

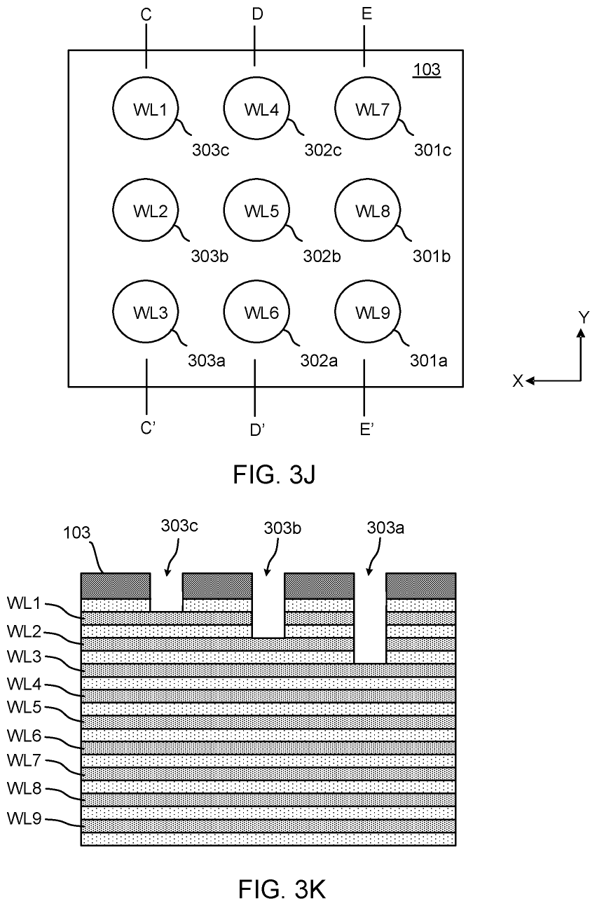

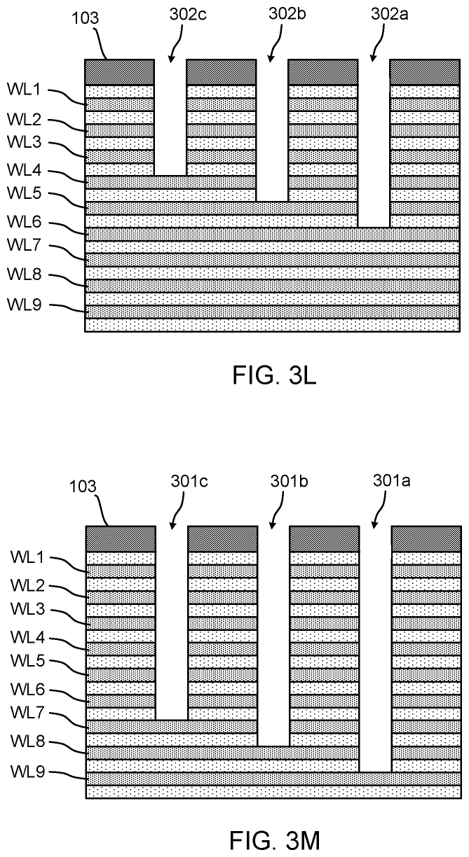

FIGS. 3A-M show exemplary processing operations to form a 3D array stack having aligned deep-trench vertical contacts.

FIG. 3A shows an exemplary embodiment of an array stack having alternating conductor layers 101a-i and insulating layers 102a-j. It will be assumed that contact holes through the array stack are to be formed to connect the conductor layers 101a-i to corresponding external word lines, for example, the conductor layers are to be connected to WL1-9 as indicated.

In an embodiment, to form the contact holes to connect the conductor layers to the WL1-9, a contact hole mask 103 is formed on top of the stack. In an embodiment, the contact hole mask 103 may be lithographically defined and etched to form the contact holes (or openings), such as holes 301a-c, 302a-c, and 303a-c. It should be noted that the holes may have any shape and form any pattern.

FIG. 3B shows the array stack illustrated in FIG. 3A and includes a pull-back mask 105 formed on top of the contact hole mask 103. The process steps illustrated and described with reference to FIGS. 2C-H can be performed to pull-back the mask 105 and etch the insulating layers and conductor layers through the exposed holes in the contact hole mask 103. However, instead of etching one conductor layer and one insulating layer at one time (e.g., after each pull-back etch operation), in this embodiment, three conductor layers and three insulating layers are etched after each pull-back operation. For example, the pull-back mask 105 is pull-back etched in the X-direction 304a. This exposes the first row of contact holes 301a-c. Next, three insulating layers and three conductor layers are etched through the exposed contact holes, for example, as indicated at 304b. After the etching process is complete, the depth of the contact holes 301a-c reaches WL4 layer as shown.

FIG. 3C shows the array illustrated in FIG. 3B with the pull-back mask 105 pulled-back or pattern-etched in the direction 304a to expose the contact holes 302a-c. As described above, three conductor layers and three insulating layers are etched through the exposed holes of the contact hole mask 103. As a result, the depth of the contact holes 302a-c reach the WL4 layer, as indicated at 304c, and the depth of the contact holes 301a-c reach the WL7 layer, as indicated at 304b.

FIG. 3D shows the array illustrated in FIG. 3C with the pull-back mask 105 pulled-back etched or pattern-etched in the direction 304a to expose the contact holes 303a-c of the mask 103. Next, one insulating layer (102a) is etched through the exposed holes 303a-c of the mask 103. After etching is completed, the depth of the contact holes 303a-c reaches the WL1 layer, as indicated at 304d.

FIG. 3E shows a top view of the array shown in FIG. 3D. The top view shows the mask 103 and the holes 301a-c, 302a-c, and 303a-c. The direction indicator 304a indicates the direction in which the pull-back mask 105 was etched to expose the openings in the mask 103. The pull-back mask 105 is now completely removed. The depth of each hole is indicated by the WL layer that is identified within each hole. For example, the hole 301a reaches the WL7 layer. Also shown in FIG. 3E is cross-section indicator B-B′ that passes through holes 301a, 302a, and 303a.

FIG. 3F shows a view of the array shown in FIG. 3D taken along the cross-section indicator B-B′. As illustrated in FIG. 3F, the etching process has resulted in the contact holes 301a, 302a, and 303a reaching the word lines layers WL7, WL4, and WL1, respectively.

FIG. 3G shows a view of the array shown in FIG. 3F. In an embodiment, the contact holes 301a, 302a, and 303a are filled with a sacrificial material, such as an oxide. The etching solution selectivity of the sacrificial material may be different from the etching solution selectivity of the conductor layers WL1-9, the insulating layers 102a-j, and the contact hole mask 103. A third mask (pull-back mask) 106 is formed on top of the first mask 103.

In another embodiment, the sacrificial material that fills the contact holes 301a, 302a, and 303a may be the same material as the insulating layers 102a-j or the conductor layers WL1-9. Therefore, in the following process steps, the sacrificial material may be etched along with the insulating layers or the conductor layers without changing etching solutions.

FIG. 3H shows a perspective view of the array shown in FIG. 3G and includes the third pull-back mask 106 that is pulled-back or pattern-etched in a second direction, such as Y-direction 304e, to expose the contact holes 301a, 302a, and 303a. The sacrificial materials in the contact holes 301a, 302a, and 303a are etched, and then an insulating layer and a word line layer are etched. The processes used in FIG. 3H are different from processes used in FIGS. 3B-D. In FIG. 3H the third mask 106 is pulled-back in the second direction 304e and with each pull-back, only one conductor layer and one insulating layer are etched through the exposed holes. Thus, after the etching process, the depths 304b, 304c, and 304d of the contact holes 301a, 302a, and 303a reach the layers WL8, WL5, and WL2, respectively.

FIG. 3I shows a view of the array shown in FIG. 3H with the pull-back mask 106 pulled-back or pattern-etched in the direction 304e to expose the next set of contact holes 301b, 302b, and 303b. As described above, the sacrificial material is etched from these holes and then one conductor layer and one insulating layer are etched through the exposed holes of the mask 103. As a result, the depths 304b, 304c, and 304d of the contact holes 301a, 302a, and 303a reach the layers WL9, WL6, and WL3, respectively. The depth 304f of the contact hole 301b reaches the layer WL8. The depths (not shown in FIG. 3I) of the contact holes 302b and 303b reach WL5 and WL2, respectively.

In the next operation, the pull-back mask 106 pulled-back or pattern-etched in the direction 304e to expose the next set of contact holes 301c, 302c, and 303c (not shown in FIG. 3I). As described above, the sacrificial material is etched from these holes, however the conductor layers and or insulating layers for these holes are not etched. As a result, the depths of the contact holes 301c, 302c and 303c reach WL7, WL4, and WL1, respectively.

FIG. 3J shows a top view of the array shown in FIG. 3I. The top view shows the mask 103 and the openings 301a-c, 302a-c, and 303a-c. The pull-back mask 106 is now completely removed. The depth of each of the openings is indicated by the WL layer identified within each opening. For example, the depth of opening 301a reaches the WL9 layer and the depth of opening 303c reaches WL1. As a result, each of the WL1-9 can be connected a particular conductor layer using a specific contact hole. Also shown in FIG. 3J are cross-section indicators C-C′, D-D′, and E-E′ that passes through openings 303, 302, and 301, respectively.

FIG. 3K shows a cross-section view of the array stack taken along cross-section indicator C-C′ shown in FIG. 3J. As illustrated in FIG. 3K the depths of the contact holes 303c, 303b, and 303a reach WL1, WL2, and WL3, respectively.

FIG. 3L shows a cross-section view of the array stack taken along the cross-section indicator D-D′ in FIG. 3J. As illustrated in FIG. 3L the depths of the contact holes 302c, 302b, and 302a reach WL4, WL5, and WL6, respectively.

FIG. 3M shows a cross-section view of the array stack taken along the cross-section indicator E-E′ in FIG. 3J. As illustrated in FIG. 3M, the depths of the contact holes 301c, 301b, and 301a reach WL7, WL8, and WL9, respectively.

Embodiments of the above described process steps form precisely aligned contact holes in a 3D array utilizing fewer etching steps than conventional processes. For example, assuming a 3D array have 64 layers. Using the disclosed processes, this array can be etched by 8 pull-back steps in the first direction (e.g., direction 304a). Each step in the first direction etches 8 conduct layers and 8 insulating layers. After that, the array may be etched by another 8 pull-back steps in the second direction (e.g., direction 304e). Each step in the second direction etches one conductor layer and one insulating layer, except that in a first step shown in FIG. 2D, it only etches one insulating layer to reach the first WL layer. After that, each step etches one WL layer and one insulting layer. At the last step shown in FIG. 2H, it still etches one WL layer and one insulting layers. This allows the contact holes 104a and 104b to reach the next lower WL layers. However, for the contact hole 104c, although it goes through the same one WL layer and one insulating layer etching, it will only etch the insulting layer 102a since there is no WL layer above it. As a result, the 64 layer array requires just 3 masking steps and 16 pull-back etch steps. This is far fewer than the 64 etching steps required by conventional staircase processes. Thus, embodiments of the invention may significantly reduce the process steps and manufacturing cost.

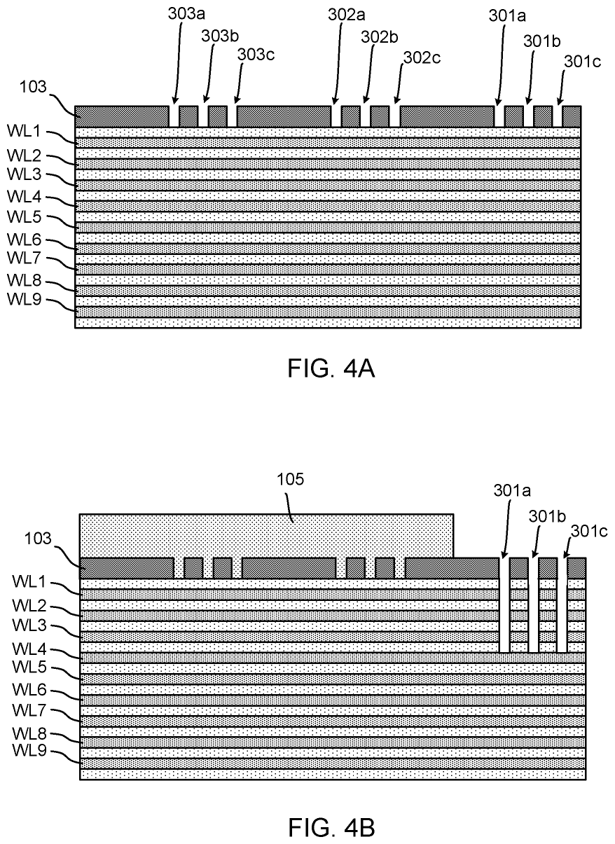

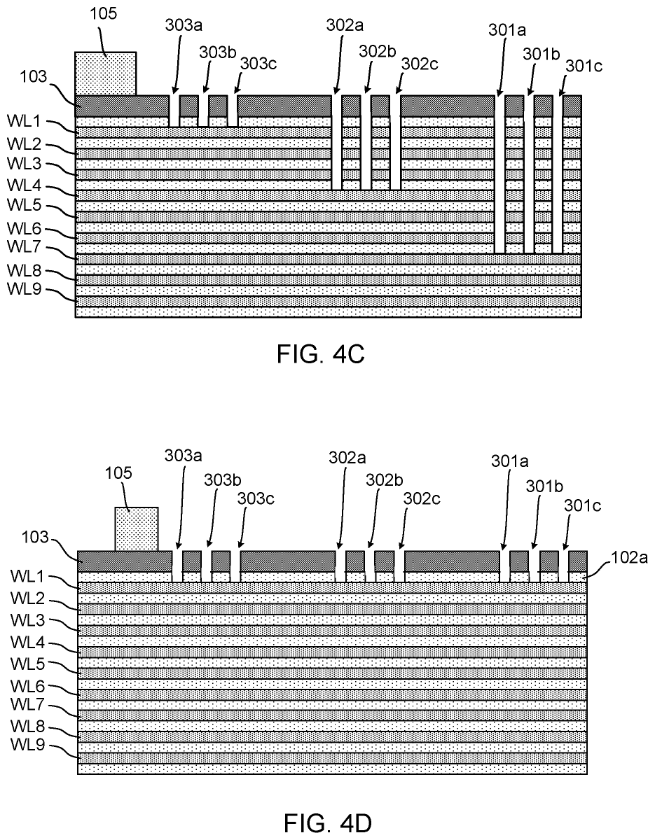

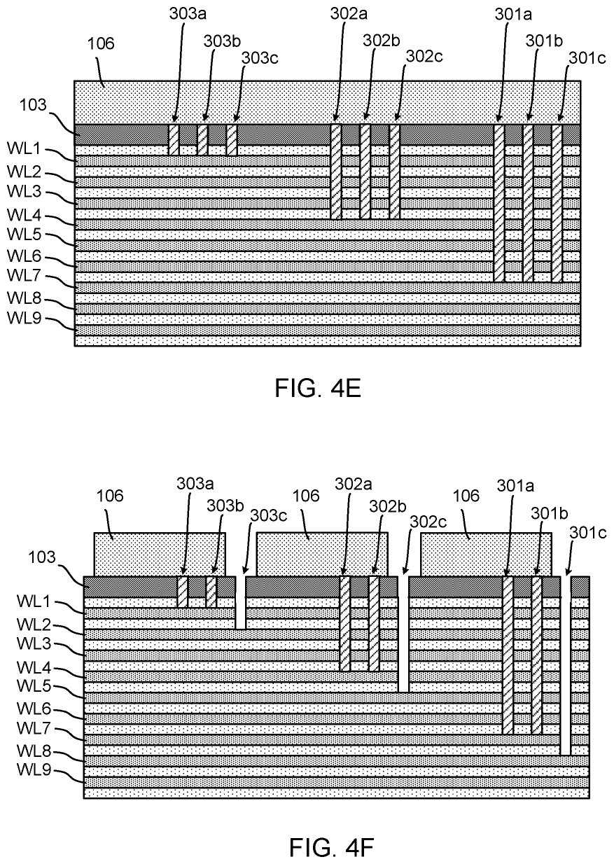

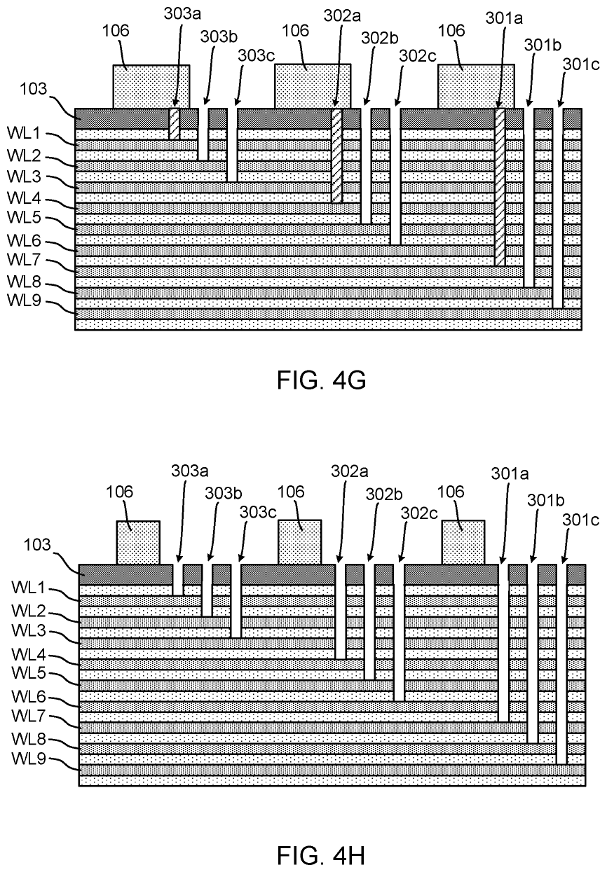

FIGS. 4A-H show exemplary processing operations to form a 3D array stack having aligned deep-trench vertical contacts.

FIG. 4A shows an array stack comprising multiple conductor layers with alternating insulating layers. For example, the conductor layers are to be connected to external word lines that are indicated by WL1-9. A hard mask 103 is formed on top of the stack to define contact holes 301a-c, 302a-c, and 303a-c.

FIG. 4B shows the array of FIG. 4A and includes a second hard mask 105 formed on top of the first mask 103. In a first etching operation, the mask 105 is pulled-back to expose the contact holes 301a-c of the mask 103. Next, three conductor layers and four insulating layers are etched through the exposed holes 301a-c of the mask 103. As a result, the depths of the contact holes 301a-c reach the WL4 layer as illustrated.

FIG. 4C shows the array of FIG. 4B with the mask 105 pulled-back in multiple operations to expose the contact holes 302a-c and 303a-c. In a second operation, the mask 105 is pull-back etched to expose the contact holes 302a-c. Next, three conductor layers and four insulating layers are etched through the exposed holes 302a-c of the mask 103. In addition, three conductor layers and three insulating layers are etched through the exposed holes 301a-c of the mask 103. In a third operation, the mask 105 pulled-back etched to expose the contact holes 303a-c. Next, one insulating layer is etched through the exposed holes 303a-c of the mask 103. As a result, the depths of the contact holes 303a-c reach the WL1 layer, the depths of the contact holes 302a-c reach the WL4 layer, and the depths of the contact holes 301a-c reach the WL7 layer.

FIG. 4D shows another embodiment that achieves the results of the process steps shown in FIGS. 4A-C. After the steps shows in FIG. 4A, an etching process is performed to etch the top insulating layer 102a using the hard mask 103. This results in the array shown in FIG. 4D. Next, the pull-back mask 105 is formed on top of the hard mask 103, and the pull-back etch process steps shown in FIGS. 4B-4C are performed. In this embodiment, each pull-back step will etch three conductor layers and three insulating layers.

FIG. 4E shows the array of FIG. 4C with the second hard mask 105 removed. The contact holes 301, 302, and 303 are filled with a sacrificial material. The selectivity for etching solutions of the sacrificial material is different from the selectivity for etching solutions of the word line layers, insulating layers, and the hard mask 103. Next, a third mask 106 for pull-back etching is deposited on top of the contact hole mask 103.

FIG. 4F shows the array of FIG. 4E with the third hard mask 106 pattern-etched as shown to expose the contact holes 301c, 302c, and 303c. Next, the sacrificial materials in the contact holes 301c, 302c, and 303c are etched, and one conductor layer and one insulating layer are etched through the exposed holes in the mask 106. As a result, the depths of the contact holes 303c, 302c, and 301c reach the WL2, WL5, and WL8 layers, respectively.

FIG. 4G shows the array of FIG. 4F with the mask 106 pull-back to expose the contact holes 301b, 302b, and 303b. Next, the sacrificial materials in the contact holes 301b, 302b, and 303b are etched. Next, one conductor layer and one insulating layer are etched through the exposed holes in the mask 106. As a result, the depths of the contact holes 303b, 302b, and 301b reach the WL2, WL5, and WL8 layers, respectively. The depths of the contact holes 303c, 302c, and 301c reach WL3, WL6, and WL9 layers, respectively.

FIG. 4H shows the array of FIG. 4G with the mask 106 pulled-back to expose the contact holes 301a, 302a, and 303a. Next, the sacrificial materials in the contact holes 301a, 302a, and 303a is etched. As a result, each of the conductor layers WL1-9 are connected to a specific one of the contact holes 303a-c, 302a-c, and 301a-c.

In an embodiment, the pull-back etch steps illustrated in FIGS. 3B-D are defined as the first ‘iteration’. The pull-back etch steps illustrated in FIGS. 3H-I are defined as the second ‘iteration’. Similarly, the pull-back etch steps illustrated in FIGS. 4B-C are defined as the first ‘iteration’ and the pull-back etch steps illustrated in FIGS. 4E-G are defined as the second ‘iteration.’

Although the previous embodiments show a two-iteration process, in other embodiments, the process may be extended to include any number of iterations.

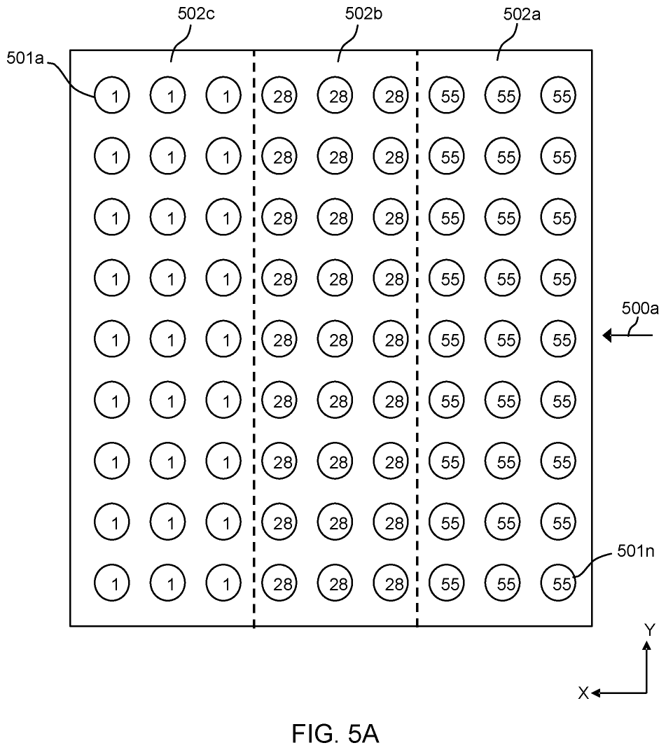

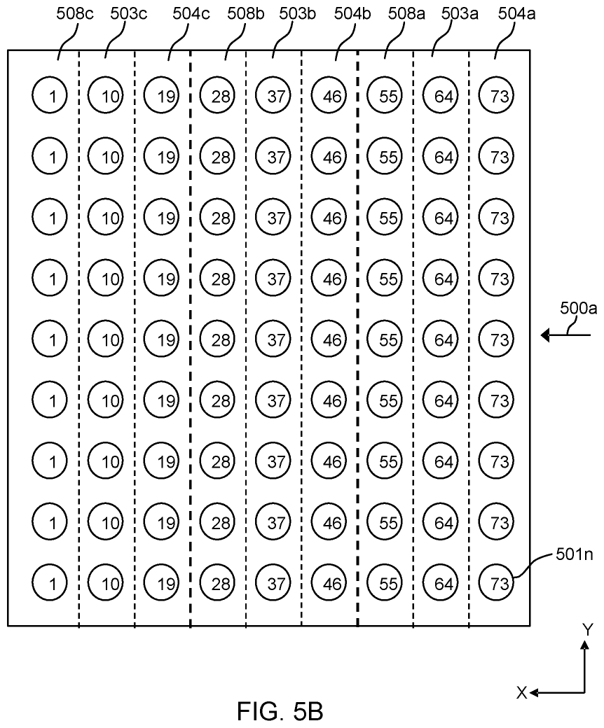

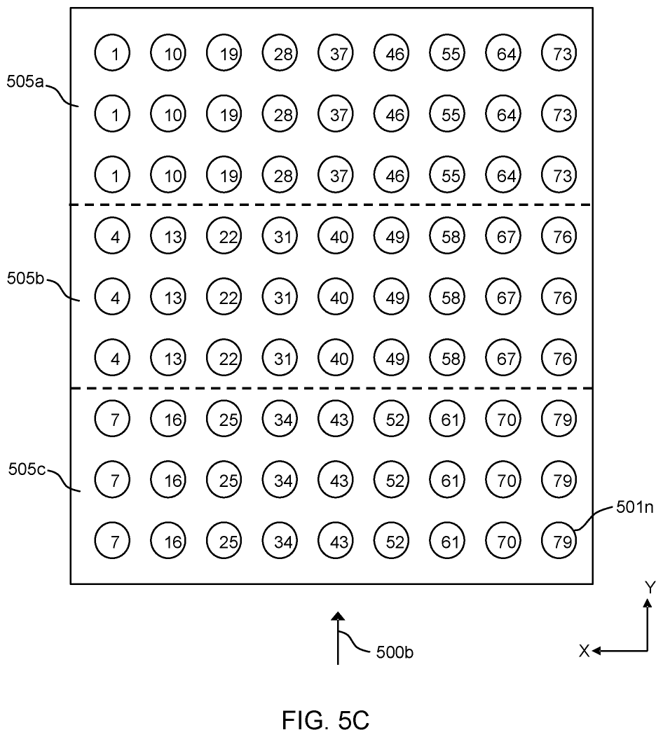

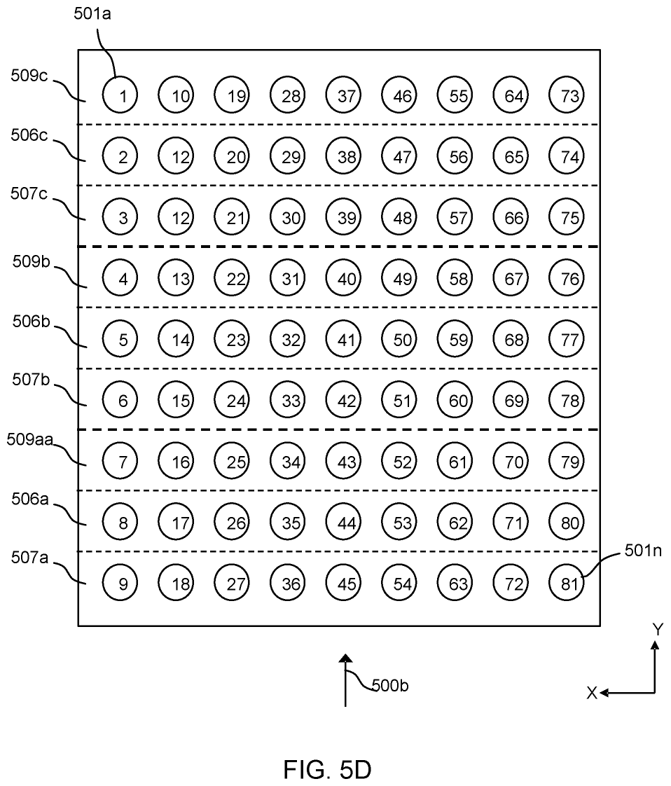

FIGS. 5A-D show exemplary processing operations to form a 3D array stack having aligned deep-trench vertical contacts. For example, FIGS. 5A-D show another embodiment for forming a 3D array that applies four iterations to etch the contact holes.

FIG. 5A shows a top view of a 3D array that illustrates contact holes formed in accordance with embodiments of the invention. It will be assumed that the 3D array shown in FIG. 5A includes eighty-one (81) conductor layer also referred to as word line layers. The circles 501a to 501n represent 81 contact holes formed in accordance with embodiments of the invention. The number shown in each contact hole represent the word line layer reached by each contact hole, (e.g., the depth of each hole).

A first iteration is performed, for example, as shown in FIGS. 4A-C. During the first iteration that is applied to the 3D array of FIG. 5A, three pull-back etches are performed in X-direction 500a. Each pull-back etch reveals three columns of contact holes and then a selected number of word line layers are etched to obtain a desired hole depth. For example, the first pull-back etch exposes three columns of holes in group 502a. The holes (in group 502a) exposed by this first pull-back operation are etched to a depth of 27 word lines. Next, the second pull-back etch reveals three columns of holes in group 502b. The holes (in groups 502a and 502b) exposed by the first and second pull-back are etched a depth of 27 word lines. Thus, the holes in group 502a have a depth of 54 word lines and the holes in group 502b have a depth of 27 word lines. Next, the third pull-back etch reveals three columns of holes in group 502c. The holes (in groups 502a, 502b, and 502c) exposed by the first, second, and third pull-back are etched to depth of 1 word line. As a result, the contact hole groups 502c, 502b, and 502a reach depths of WL1, WL28, and WL55 layers, respectively.

FIG. 5B shows the 3D array of FIG. 5A and illustrates a second iteration, for example, as shown in FIGS. 4D-G, where the hard mask 103 is pull-back etched in the X-direction 500a in three separate sections. The holes exposed after each pull-back operation are etched a depth of nine word line layers. Thus, in the first pull-back operation, the holes in groups 504a-c are exposed. Next, the holes in groups 504a-c are etched a depth of nine word line layers. During a second pull-back operation, the holes in groups 503a-c are exposed. Next, the holes in groups 504a-c and 503a-c are etched a depth of nine word line layers. During a third pull-back operation, the mask is removed from the 3D array exposing holes in groups 508a-c. As a result, the holes in groups 503a-c are etched 9 word line layers, the holes in groups 504a-c are etched 18 word line layers, and the holes in groups 508a-c are not etched any further. Thus, the hole 501n had a depth of WL55 layers after the first iteration and now has a depth of WL73 after the second iteration.

FIG. 5C shows the 3D array of FIG. 5B and illustrates a third iteration, for example, as shown in FIGS. 4A-C, where the hard mask 103 is pull-back etched in the Y direction 500b in three sections. The holes exposed after each pull-back operation are etched a depth of three word line layers. Thus, in the first pull-back operation, the holes in group 505c are exposed. Next, the exposed holes in group 505c are etched a depth of three word line layers. During a second pull-back operation, the holes in groups 505b are exposed. Next, the exposed holes in groups 505c and 505b are etched a depth of three word line layers. During a third pull-back operation, the mask is removed from the 3D array exposing holes in group 505a. As a result, the holes in group 505c are etched six word line layers, the holes in group 505b are etched 3 word line layers, and the holes in group 505a are not etched any further. Thus, the hole 501n had a depth of WL73 after the second iteration and now has a depth of WL79 after the third iteration.

FIG. 5D shows the 3D array of FIG. 5C and illustrates a fourth iteration, for example, as shown in FIGS. 4D-G, where the hard mask 103 is pull-back etched in the Y direction 500b in three divided sections, and after each pull-back 1 word line layer is etched.

Thus, in the first pull-back operation, the holes in groups 507a-c are exposed. Next, the exposed holes in groups 507a-c are etched a depth of one word line layer. During a second pull-back operation, the holes in groups 506a-c are exposed. Next, the exposed holes in groups 506a-c and 507a-c are etched a depth of one word line layer. During a third pull-back operation, the mask is removed from the 3D array exposing holes in groups 509a-c. As a result, the holes in groups 506a-c are etched one word line layer, the holes in groups 507a-c are etched 2 word line layers, and the holes in groups 509a-c are not etched any further. Thus, the hole 501n had a depth of WL79 layers after the third iteration and now has a depth of WL81 after the fourth iteration. As a result, the 81 contact holes 501a-n of the 3D array are etched to reach the 81 word line layers.

In the exemplary embodiments described above, the total pull-back etch operations are 12 instead of 81 for conventional pull-back operations. This reduction in the number of operations significantly reduces the process time and cost. For example, an array having 256-word line layers can be etched by using 4 iterations with each iteration comprising 4 pull-back etch operations. Thus, the total pull-back etch operations are only 4+4+4+4=16. This significantly reduces the number of pull-back etches to only about 6% of conventional methods, which would require 256 etch operations. It should also be noted that in various embodiments, the contact holes may have any shape, any dimension, and any pattern.

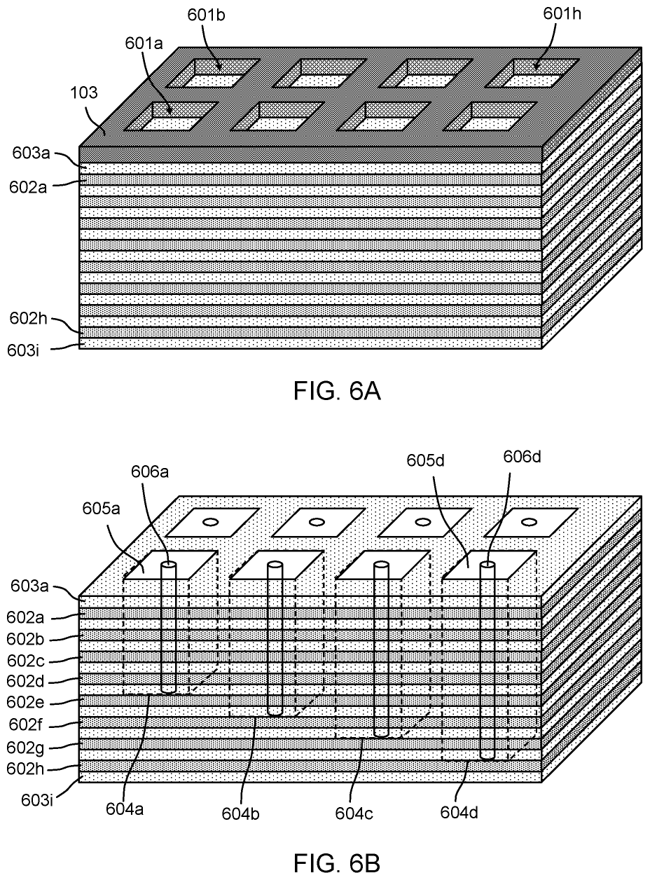

FIGS. 6A-B show exemplary processing operations to form a 3D array stack having aligned deep-trench vertical contacts and that utilize square contact holes.

FIG. 6A shows an exemplary 3D array where the hard mask 103 has large square or rectangle contact holes 601a-h. For example, the array includes alternating word line layers 602a-h and insulating layers 603a-i. The hard mask 103 is formed on top of the array stack.

FIG. 6B shows the 3D array of FIG. 6A and illustrates how the above-described processes are used to etch square contact holes (or openings) 604a-d through the hard mask 103 to reach different word line layers. For example, the contact hole 604a has a depth that reaches word line layer 602e. The large contact holes may be filled with insulator 605a-d. Next, small contact holes 606a-d are formed by using deep trench process to etch through the insulators 605a-d to reach the appropriate word line layers. Next, the small contact holes 606a-d are filled with conductor material, such as metal or other suitable material.

In various embodiments, the etch process using a hard mask as described herein has significant benefits and advantages over the traditional ‘staircase’ etch process. For example, first, the hard mask eliminates the misalignment between the contact holes to the staircases. Second, it eliminates the accumulated misalignment of the pull-back etch in the traditional staircase process. Third, the embodiment's contact hole pitch may be more compact than in the traditional process. Fourth, the embodiments are easier to align the contact holes with the top metal layers.

The conventional process requires landing the deep-trenched contact holes on the word line staircase. Due to the height of the 3D array, which is about 2 to 3 um, this causes significant process challenges in aligning the small contact hole pattern on top of the array and the word line layers. Therefore, the conventional process requires very wide staircase, such as 1 um for each stair step. This not only increases the size penalty of the staircase, but also reduces process yield.

In contrast, the disclosed embodiments directly etch the contact holes layer by layer to reach the target word line layers. Thus, there is no misalignment concern. The contact holes pitch may be much smaller than the conventional process and the process yield is significantly increased.

It should be noted that the exemplary embodiments are not limited to just forming word line contacts in a 3D array. In other embodiments, the disclosed embodiments may be combined with other processing methods as described below.

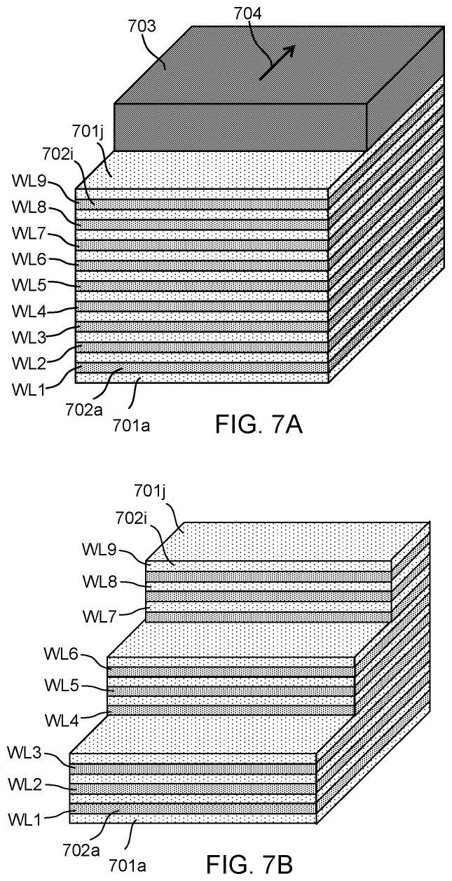

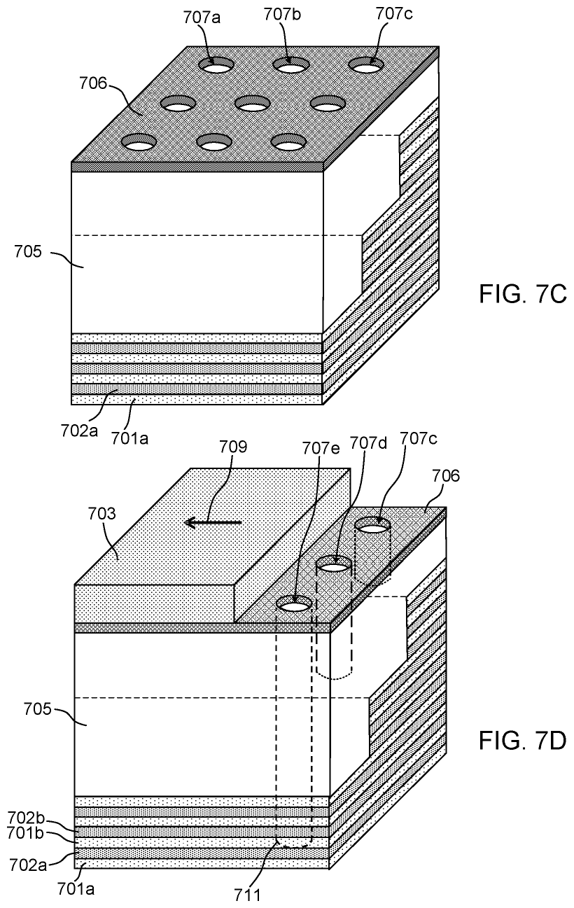

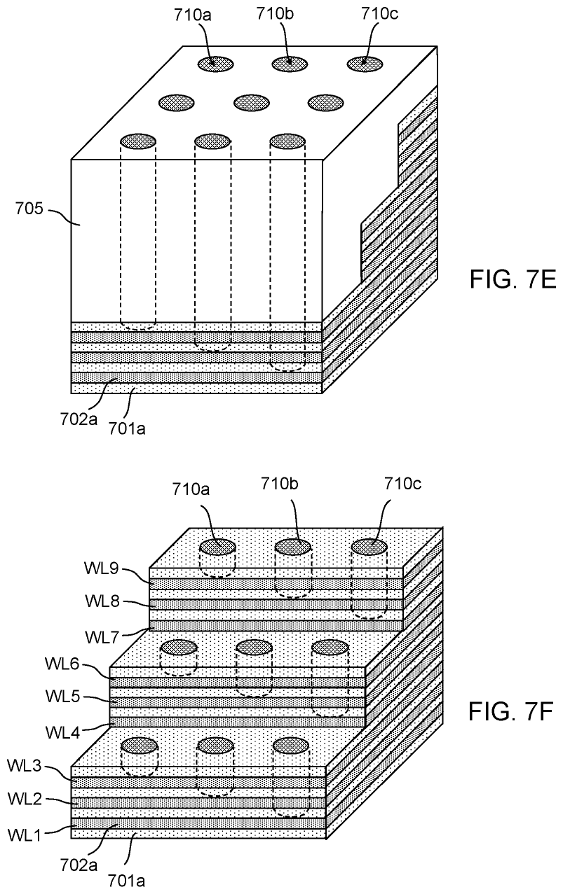

FIGS. 7A-F show exemplary processing operations to form a 3D array stack having aligned deep-trench vertical contacts and that utilize staircase etching processes to form word line contacts.

FIG. 7A shows a 3D array that comprises alternating insulating layers 701a-j and conductor layers 702a-i that are deposited to form a word line stack. For clarity, the conductor layers 702a-i are referred to as “WL1” to “WL9.” A pull-back mask 703 is formed on top of the stack and pull-back etched in the first direction 704. The pull-back etching is performed two times. Each time, three word line layers are etched to form a stair step configuration.

FIG. 7B shows the array of FIG. 7A after stair step etching is performed. As a result, the stack becomes three stair steps with each stair step containing three word line layers.

FIG. 7C shows the array of FIG. 7B after an insulating layer 705 is deposited to cover the stairs and flatten by a planarization process, such as CMP (Chemical Mechanical Planarization). Next, a hard mask 706 is formed on top of the insulating layer 705. The hard mask 706 is patterned and etched to form contact holes (or openings), such as holes 707a-c.

FIG. 7D shows the array of FIG. 7C after a pull-back mask 703 is formed on top of the hard mask 706. Next, the pull-back mask 706 is pull-back etched in the second direction 709. The pull-back etching is performed three times. Each time the pull-back etching of the mask 703 reveals three contact holes in the hard mask 703, such as holes 707c-e. Next, an anisotropic etching process is performed in the exposed contact holes to etch through the insulating layer 705, and one or more insulating and conductor layers to extend the depth of the hole to the desired word line layer. For example, the hole 707e is etched through the layer 705 and all the way through the conducting layer 702b and the insulating layer 701b to reach the conducting layer 702a, as illustrated at 711. A similar process is used to etch the holes 707d and 707c to the appropriate conductor layers.

FIG. 7E shows the array of FIG. 7D after the etching process is completed to form nine contact holes, such as holes 710a-c, that each have the desired depth. For example, each contact hole is connected to one word line layer. The hard mask 706 has been removed.

FIG. 7F shows the array of FIG. 7E after the insulating layer 705 is removed to show the contact holes 710a-c and their connection to each word line layer. After the contact holes are formed, the process described in FIGS. 2H-L may be performed to connect the word line layers to outside circuits, such as decoder circuits.

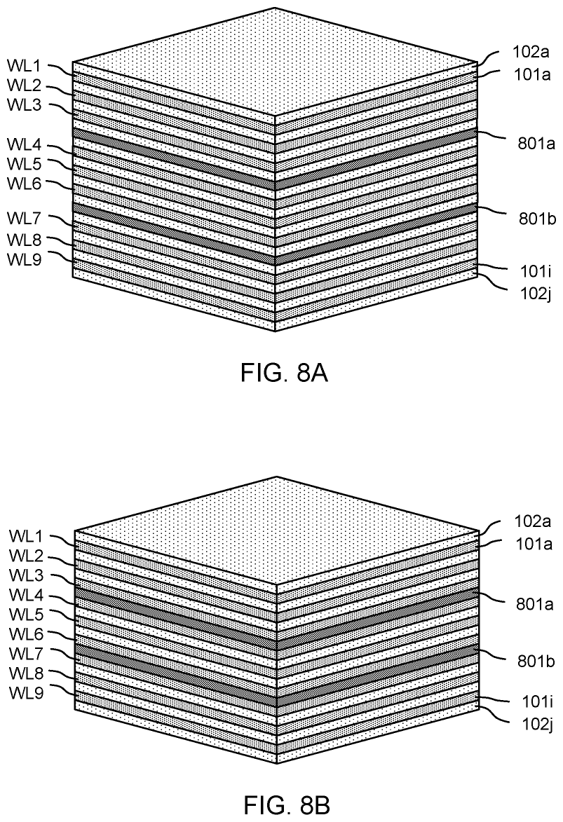

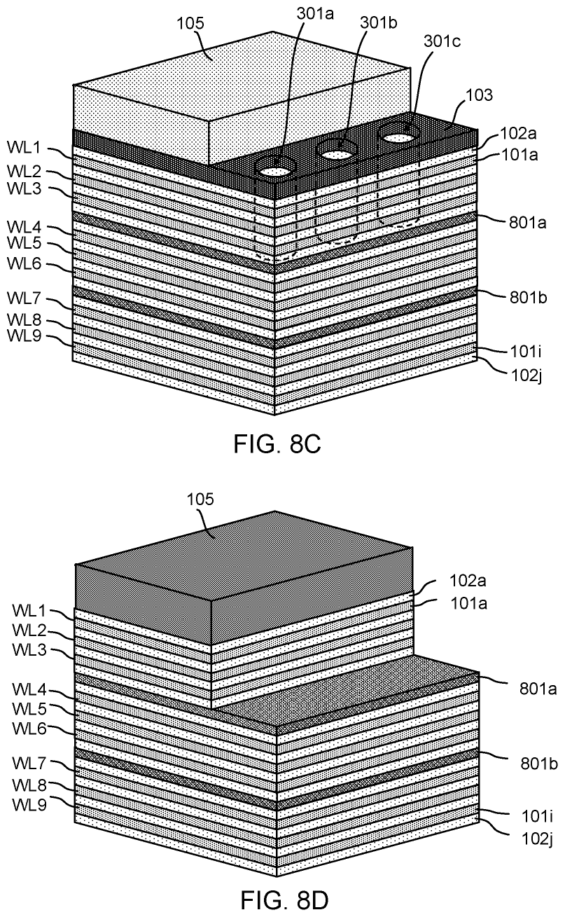

FIGS. 8A-D show exemplary processing operations to form a 3D array stack having aligned deep-trench vertical contacts and that utilizes etch stop layers and staircase etching processes to form word line contacts.

FIGS. 8A-B show 3D array stacks formed by alternately depositing multiple conductor layers 101a-i and insulating layers 102a-j. In an embodiment, ‘etching-stop’ layers, such as 801a and 801b are deposited between WL3 and WL4, and WL6 and WL7, respectively. The etching-stop layers may have different selectivity for etching solution than the conductor layers and the insulating layers. The etching-stop layers may be inserted between insulating layers as shown in FIG. 8A, or directly replace selected insulating layers between the conductor layers, as shown in FIG. 8B.

FIG. 8C shows the array of FIG. 8A onto which a hard mask 103 and a pull-back mask 105 are deposited. After the pull-back mask 105 is etched back in a first direction, an etching solution is used that can etch both the conductor layers and insulating layers but not the etching-stop layer 801a. Therefore, the contact holes 301a-c can be formed in one step by etching through all the conductor layers and insulating layers above the etching-stop layer 801a. Next, an etching process is performed to etch the etching-stop layer 801a. Next, the mask 105 is pull-back etched and a second etch may be performed on the exposed holes. For the contact holes 301a-c, the etching process will etch in one step through all the layers above the second etching-stop layer 801b. Then, another etching process is performed to etch the second etching-stop layer 801b.

In contrast with the processes illustrated and described with reference to FIG. 3B, using the processes described with reference to FIG. 8C allows the contact holes 301a-c to be formed by alternately changing the etching solution to etch the conductor layers and insulating layers layer by layer. As a result, the process shown in FIG. 8C is faster and cheaper than the process in FIG. 3B, especially when the number of layers is large.

FIG. 8D illustrates how the above process can be applied to the traditional staircase etch technique. By using the etching-stop layers 801a and 801b, when etching multiple layers in the first direction, all the layers above the etching-stop layer 801a may be etched in one step. Then, an etching process is performed to etch the etching-stop layer 801a. After that, the mask 105 may be pulled back and the second etch may be performed to etch through all the layers above the second etching-stop layer 801b in one step. Then, another etching process is performed to etch the second etching-stop layer 801b.

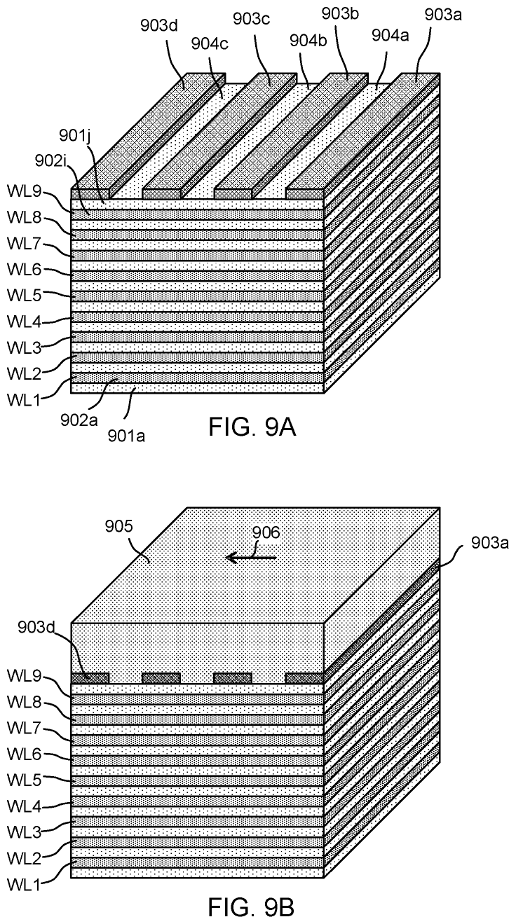

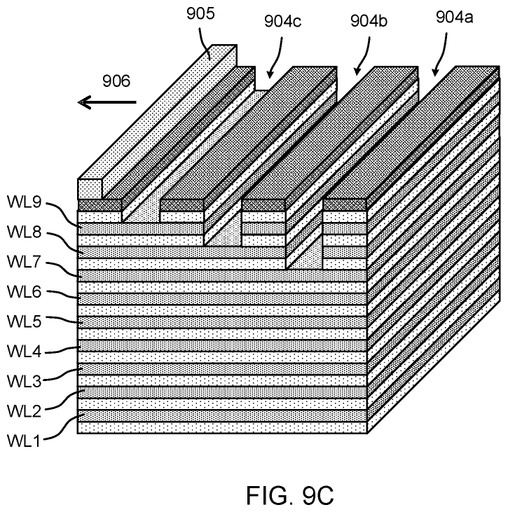

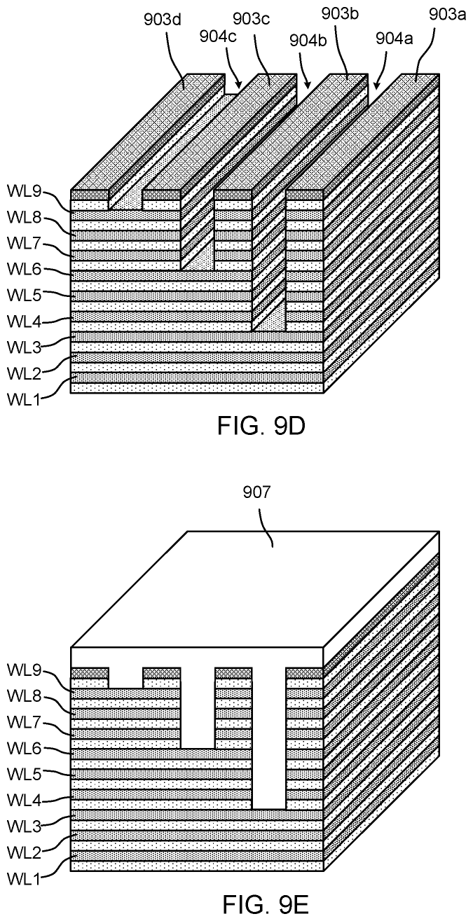

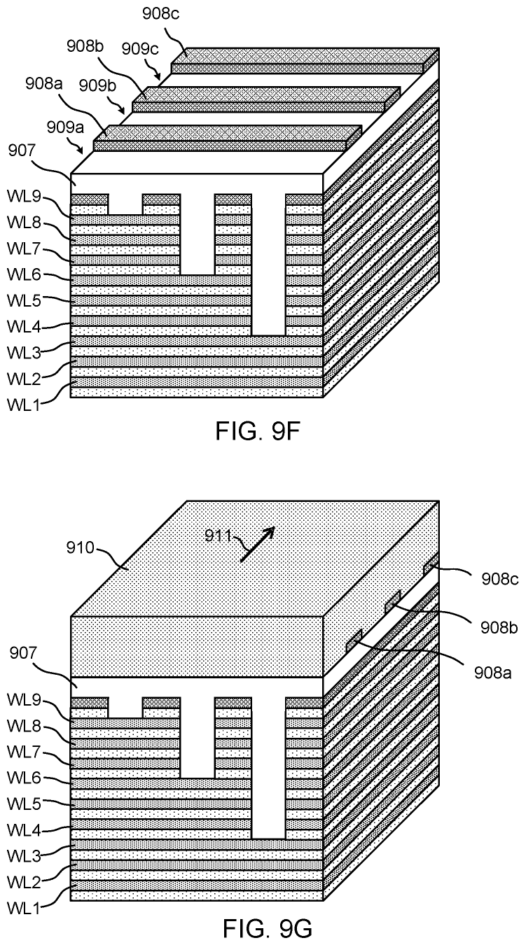

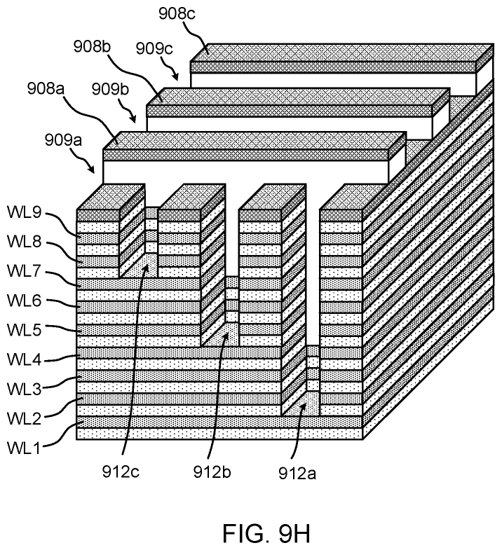

FIGS. 9A-H show exemplary processing operations to form a 3D array stack having aligned deep-trench vertical contacts and that utilizes a line pattern hard mask.

FIG. 9A shows a 3D array having multiple insulating layers 901a-j and multiple conductor layers 902a-i that are alternately deposited to form a word line stack. For clarity, the conductor layers 902a-i are referred to as ‘WL1’ to ‘WL9’, respectively. A hard mask with line patterns 903a-d is formed on top of the stack to expose the areas 904a-c.

FIG. 9B shows the array of FIG. 9A with a pull-back mask 905 formed on top of the hard masks 903a-d. Next, multiple pull-back etch steps, as shown in FIGS. 2B-H are performed in the direction 906. In one embodiment, the pull-back etch may be performed in only one direction. Assuming the pattern mask 903 has 9 line patterns, each pull-back step reveals one line pattern and is used to etch one insulating layer and one conductor layer. For example, the first pull-back step reveals the area 904a and etches 1 insulating layer 901j and 1 conductor layer 902i. The second pull-back step reveals the area 904b and etches 1 insulation layer and 1 conductor layer. The third pull-back step reveals the area 904c and etches 1 insulating layer.

FIG. 9C shows the array of FIG. 9B after the previously described pull-back etch steps. The slits in the areas 904a, 904b, and 904c reach WL7, WL8, and WL9, respectively. The pull-back steps may be continued for total 9 steps. As a result, the 9 slits will reach WL1 to WL9, respectively.

In another embodiment, the pull-back etch may be performed in two directions, similar to the previous embodiment shown in FIGS. 3A-I.

FIG. 9D shows the array of FIG. 9A. During the pull-back steps shown in FIG. 9B, the first pull-back step reveals the area 904a and etches 3 insulating layers and 3 conductor layers. The second pull-back step further reveals the area 904b and etches 3 more insulation layers and 3 conductor layers for both areas 904a-b. The third pull-back step further reveals the area 904c and etches one insulating layer for the areas 904a-c. Thus, FIG. 9D shows the stack after the pull-back etch in the first direction is completed.

FIG. 9E shows the array of FIG. 9D after the slits in areas 904a-c are filled with an insulating layer 907.

FIG. 9F shows the array of FIG. 9E after second line pattern hard masks 908a-c are formed on top of the stack to expose the areas 909a-c.

FIG. 9G shows the array of FIG. 9F after a second pull-back mask 910 is formed on top of the second hard masks 908a-c. Next, multiple pull-back etch steps as shown in FIGS. 2B-H are performed in the second direction 911. The first pull-back step reveals the area 909a and etches the insulating layer 907, one conductor layer, and one insulating layer. The second pull-back step further reveals the area 909b and etches the insulating layer 907, one conductor layer, and one insulating layer.

FIG. 9H shows the array of FIG. 9G after the pull-back etch steps. After the etch steps described above, the contact holes, such as 912a-c in the areas 909a-c are connected to WL1 to WL9. After that, the contact holes may be connected to external circuits or decoders using the process steps shown in FIGS. 2I-L, or the process steps shown in FIG. 6B.

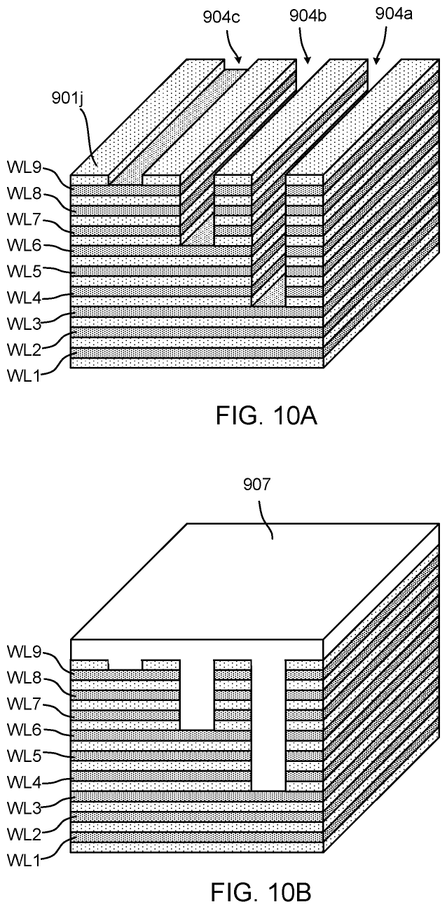

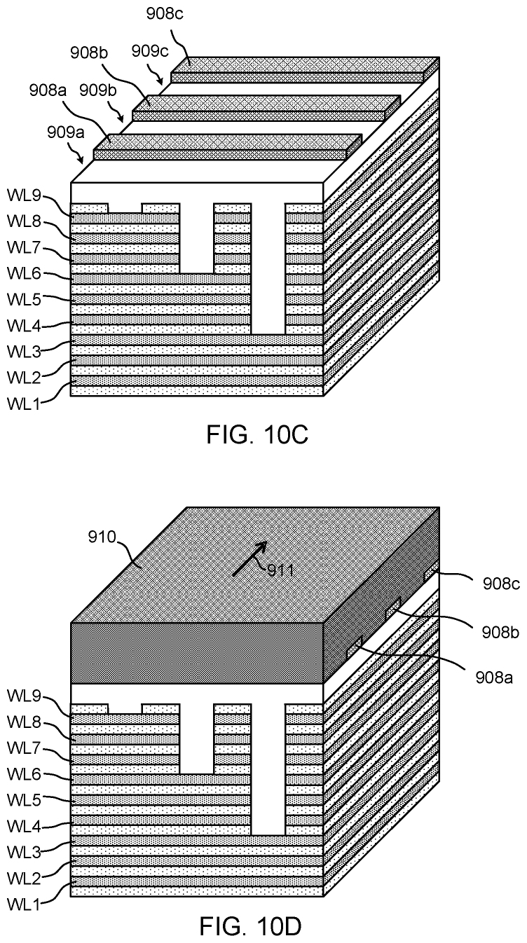

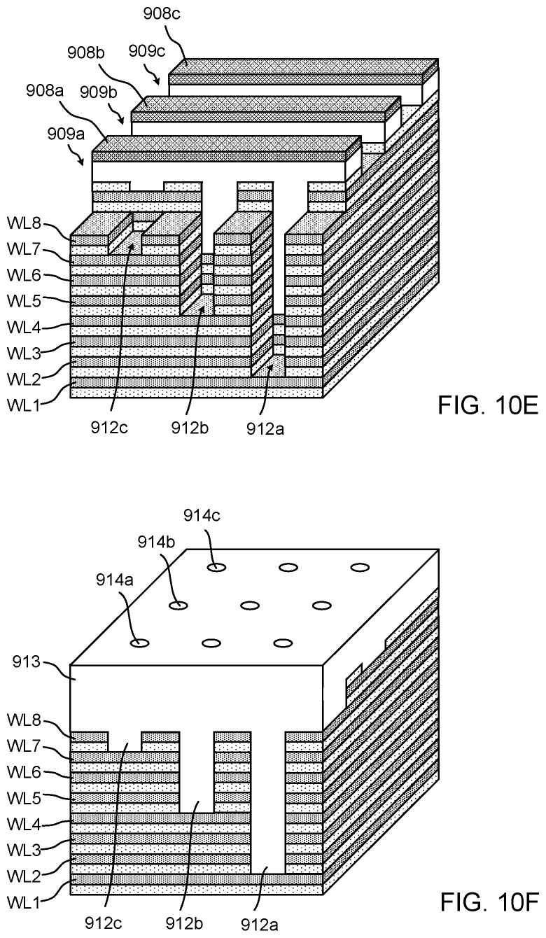

FIGS. 10A-F show exemplary processing operations to form a 3D array stack having aligned deep-trench vertical contacts and that utilizes line pattern hard masks.

FIG. 10A shows a 3D array that is similar to the embodiment shown in FIGS. 9A-D except that after the process step shown in FIG. 9D is performed, the first hard masks 903a-d are removed leaving an insulator layer 901j on top of the stack.

FIG. 10B shows the array of FIG. 10A after the slits in areas 904a-c are filled with insulating layer 907.

FIG. 10C shows the array of FIG. 10B after the second hard masks 908a-c are formed on top of the stack to expose the areas 909a-c.

FIG. 10D shows the array of FIG. 10C after a second pull-back mask 910 is formed on top of the second hard masks 908a-c. Next, multiple pull-back etch steps as shown in FIGS. 2B-H are performed in the direction 911. The first pull-back step reveals the area 909a and etches the insulating layer 907, one conductor layer, and one insulating layer. The second pull-back step further reveals the area 909b and etches the insulating layer 907, one conductor layer, and one insulating layer.

FIG. 10E shows the array of FIG. 10D after the pull-back etch steps. After the etching steps above, the contact holes, such as 912a-c in the areas 909a-c are connected to WL1 to WL9. After that, the contact holes may be connected to decoders using the process steps shown in FIGS. 2I-L, or the process steps shown in FIG. 6B.

FIG. 10F shows the array of FIG. 10E that is processed using the process step shown in FIG. 6B. The insulating layer 913 is formed to fill the contact holes, and then multiple contact holes, such as holes 914a-c are formed by using a deep trench process to connect to WL1 to WL9.

It should be noted that in the embodiments shown in FIGS. 9A-H and FIGS. 10A-F, the contact hole patterns are defined by hard masks 903a-d and hard masks 908a-c. As a result, the accumulated misalignment problem of the traditional word line staircase pull-back etching process is eliminated.

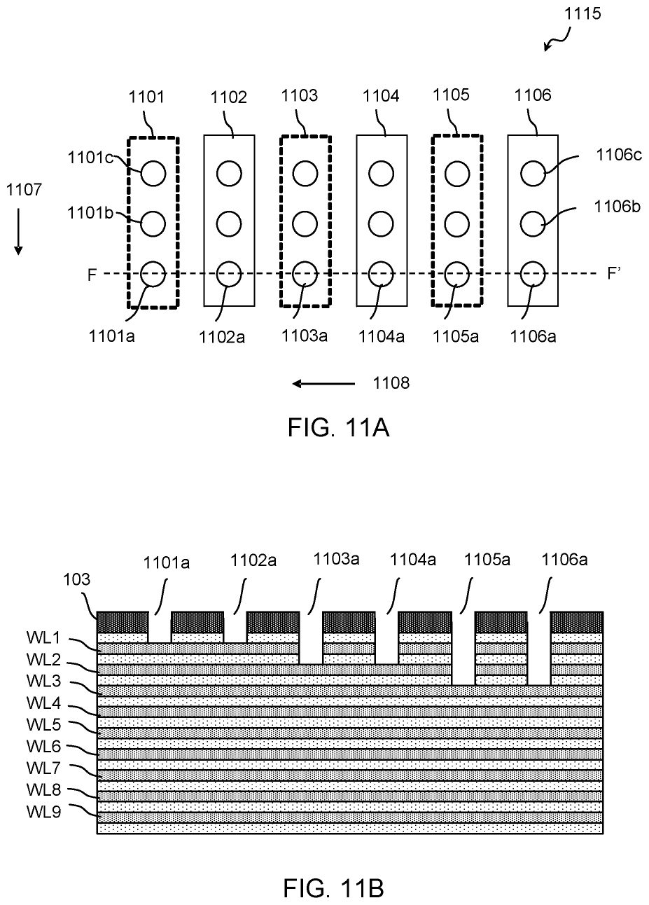

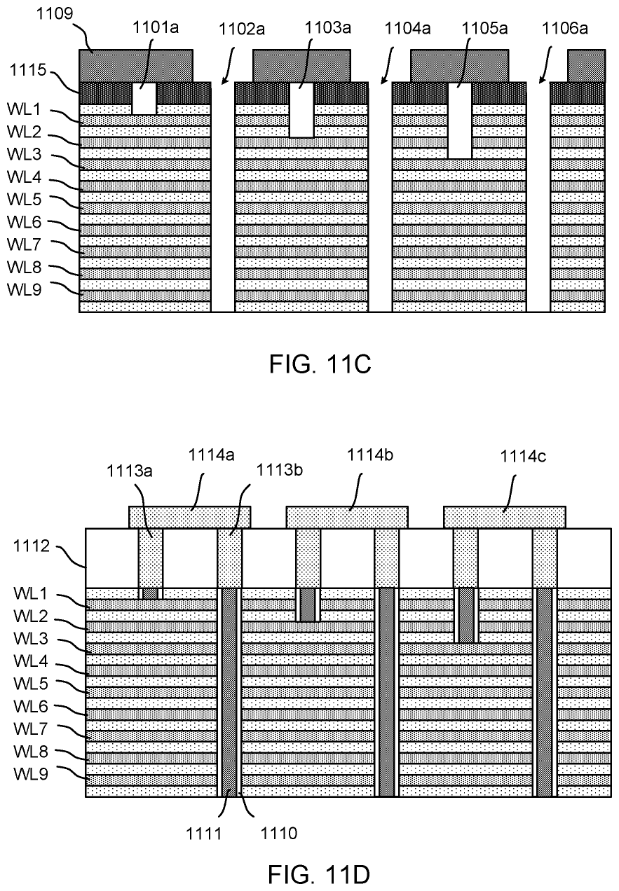

FIGS. 11A-D show exemplary processing operations to form a 3D array stack having aligned deep-trench vertical contacts and that connect with circuitry under the array.

FIG. 11A shows the top view of a contact hole mask 1115. The contact holes are divided into two groups. The first group is ‘word line contact holes’ such as contact holes 1101, 1103, and 1105. The second group is ‘decoder contact holes’ such as contact holes 1102, 1104, and 1106. FIG. 11A also shows cross-section indicator F-F′. This embodiment uses a two-direction pull-back etch process as described in the embodiment shown in FIGS. 3A-M. For simplicity, the detailed process steps shown in FIGS. 3A-M are not repeated here. During the first etch pull-back, the pull-back mask is etched in the direction 1107. Each pull-back etch reveals one row of the contact holes after which 3 word line layers are etched within the exposed holes. As a result, the contact holes in the first row (1101c to 1106c) will be etched for 6 word line layers, and the contact holes in the second row (1101b to 1106b) will be etched for 3 word line layers.

The second pull-back etch pulls back the second pull-back mask in the direction 1108. In this step, each pull-back will reveal two columns of contact holes. For example, the first pull-back will reveal the contact holes in groups 1106 and 1105. The second pull-back etch will reveal the contact holes in groups 1104 and 1103. After each pull-back, one word line layer is etched. As a result, the word line contact holes in groups 1101, 1103, and 1105 will reach the word line layer WL1 to WL9, respectively. Similarly, the decoder contact holes in groups 1102, 1104, and 1106 will also reach the word line layer WL1 to WL9, respectively.

FIG. 11B shows a cross-section view of the array in FIG. 11A taken along the cross-section indicator F-F′ shown in FIG. 11A. As shown in FIG. 11B, the word line contact holes 1101a, 1103a, and 1105a reach the word line layer WL1, WL2, and WL3, respectively. Similarly, the decoder contact holes 1102a, 1104a, and 1106a also reach the word line layer WL1, WL2, and WL3, respectively.

FIG. 11C shows the array of FIG. 11B after another mask 1109 is formed on top of the contact hole mask 1115. The mask 1109 covers the word line contact holes, such as holes 1101a, 1103a, and 1105a, and reveals the decoder contact holes, such as holes 1102a, 1104a, and 1106a as shown. Next, an etch process etches through all the word line layers and insulating layers in the decoder contact holes and reaches the decoder circuit that is located under the array. For example, the etched decoder contact holes may land on metals or diffusions below the array.

FIG. 11D shows the array of FIG. 11C after the hard masks 1115 and 1109 are removed and a dielectric layer or insulating layer 1110 is formed on the sidewalls of all the word line contact holes and the decoder contact holes. Next, all the contact holes are filled with conductor material 1111, such as metal to form the contacts. An insulating layer 1112 is formed on top of the array. Next, contacts, such as 1113a and 1113b and conductor layers, such as metal 1114a-c are formed to connect the word line contacts and the decoder contacts as shown in FIG. 11D. As a result, the word line layers are connected to the decoder circuit under the array.

Please notice, in the previous embodiment, the contact holes for word line layer and decoder circuit are defined by the same hard mask 1115. This takes full advantage of the various embodiments provided in accordance with the invention because the misalignment between the contact holes is eliminated by using the hard mask.

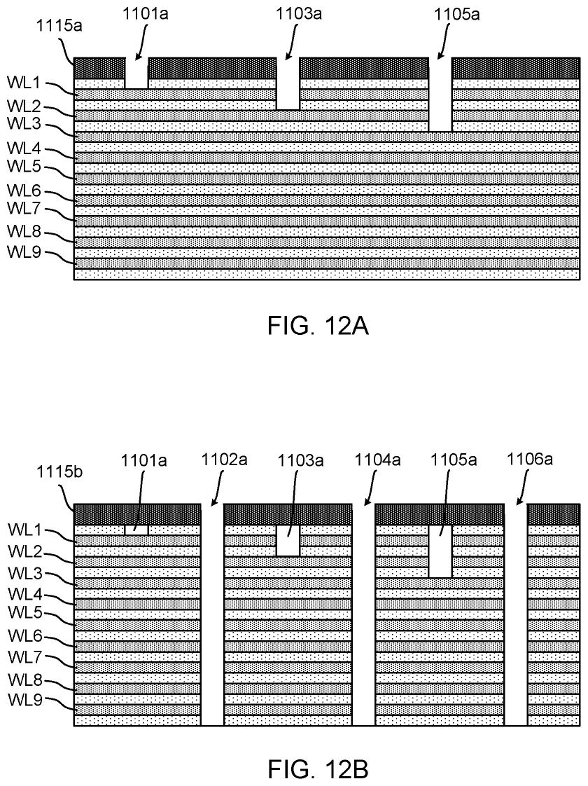

FIGS. 12A-B show exemplary processing operations to form a 3D array stack having aligned deep-trench vertical contacts and that connect with circuitry under the array. This embodiment is similar to the embodiment described with reference to FIGS. 11A-D except that the word line contact holes and the decoder contact holes are defined by different masks.

FIG. 12A shows the array of FIG. 11A taken along cross-section indicator F-F′. In this embodiment, the word line contact holes, such as 1101a, 1103a, and 1105a are defined and etched by using a first mask 1115a.

FIG. 12B shows the 3D array of FIG. 12A after the first mask 1115a is removed. The word line contact holes 1101a, 1103a, and 1105a are filled with a sacrificial material. Next, a second mask 1115b is formed to define the decoder contact holes. An etch process is performed to etch through all the word line layers and insulating layers to form the decoder contact holes 1102a, 1104a, and 1106a. After that, the second mask 1115b is removed and the sacrificial materials in the word line contact holes are removed. Next, the process steps shown in FIG. 11D are performed to connect the word line layers to the decoder under the array.

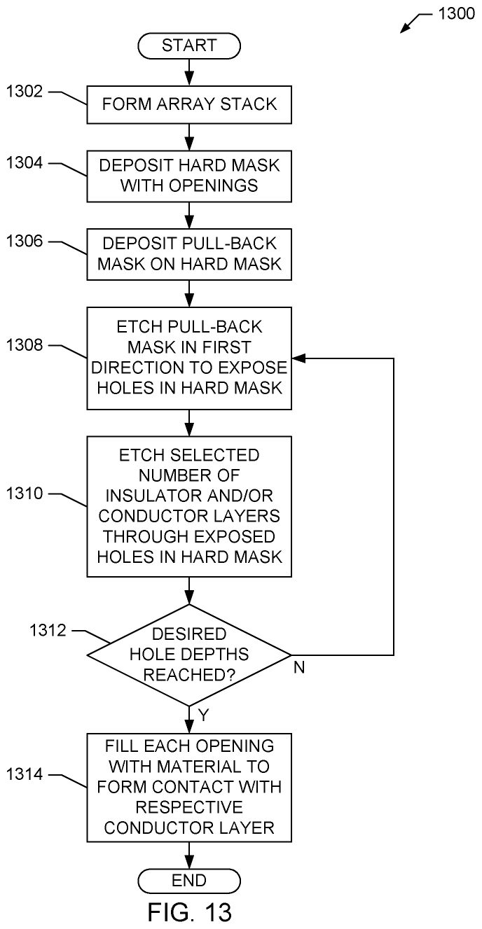

FIG. 13 shows an exemplary method 1300 for forming a 3D array having aligned deep-trench vertical contacts. For example, the method 1300 is suitable to forms the arrays as described herein.

At block 1302, a 3D array stack is formed. For example, the 3D array stack comprises alternating conductor 101 and insulator 102 layers as illustrated in FIG. 1.

At block 1304, a hard mask is deposited on top of the 3D array stack. For example, the hard mask 103 is deposited on the 3D array stack as illustrated in FIG. 1. The hard mask precisely defines one or more holes or openings having any desired size, shape, and pattern. The hard mask has an etching material selectivity that is different from the conductor and insulator layers so that it is possible to etch the conductor and insulator layers through the openings in the hard mask without etching the hard mask itself. In another embodiment, the hard mask comprises line patterns 903 as illustrated in FIG. 9A.

At block 1306, a pull-back mask is deposited on the hard mask. For example, the pull-back mask 105 is deposited on the hard mask 103 as illustrated in FIG. 2B

At block 1308, the pull-back mask is etched in a particular direction to expose one or more holes or openings in the hard mask. For example, the pull-back mask 105 is etched in the direction 202 to expose the holes 104 in the hard mask 103 as illustrated in FIG. 2C. As illustrated in the exploded view 206 of FIG. 2C, the pull-back mask etching need not be precise since the openings in the hard mask precisely define the size, shape and location of the contact holes to be formed through the 3D array. Thus, the pull-back mask need only be etched to pull-back the front edge 214 with the range 216 to expose the contact hole 104a. In another embodiment, the pull-back mask in etched in sections, as illustrated in FIGS. 4F-H, so that various etching patterns can be achieved as described herein.

At block 1310, a selected number or insulator and/or conductor layers are etched through the exposed openings in the hard mask. For example, as illustrated in FIG. 2F, one or more insulator and/or one conductor layers are etched through the exposed openings in the hard mask 103. In another embodiment, illustrated in FIG. 3B, three conductor and insulators layers are etched through the exposed openings in the hard mask 103. Thus, in various embodiments, any number or conductor and/or insulator layers may be etched through an exposed opening in the hard mask.

At block 1312, a determination is made as to whether the desired hole depths associated with the openings in the hard mask have been reached. For example, each opening in the hard mask is designed to be deep enough provide a contact to a particular conductor layer in the 3D array stack. For example, as illustrated in FIG. 3J, each opening is deep enough to reach a particular conductor layer of the 3D array. If the desired hole depths are reached, the method ends. If the desired hole depths are not reached, the method proceeds to block 1308 where the pull-back mask is again etched to expose more holes in the hard mask and etching of the conductor and insulator layers can be performed.

Thus, the method 1300 operates to form a 3D array with precisely aligned deep trench contacts. It should be noted that the operation of the method 1300 may be modified, rearranged, deleted, added to, or otherwise changed within the scope of the embodiments.

It should be noted that the method 1300 can be extended to perform pull-back mask operations in multiple directions. For example, prior to performing the operations provided in block 1314, the method can continue at block 1306 where a second pull-back mask is deposited. At block 1308, the second pull-back mask is pull-back etched in a second direction. The method continues until etching in the second direction is completed. After pull-back etching in all directions is completed, the operations at block 1314 then can be performed.

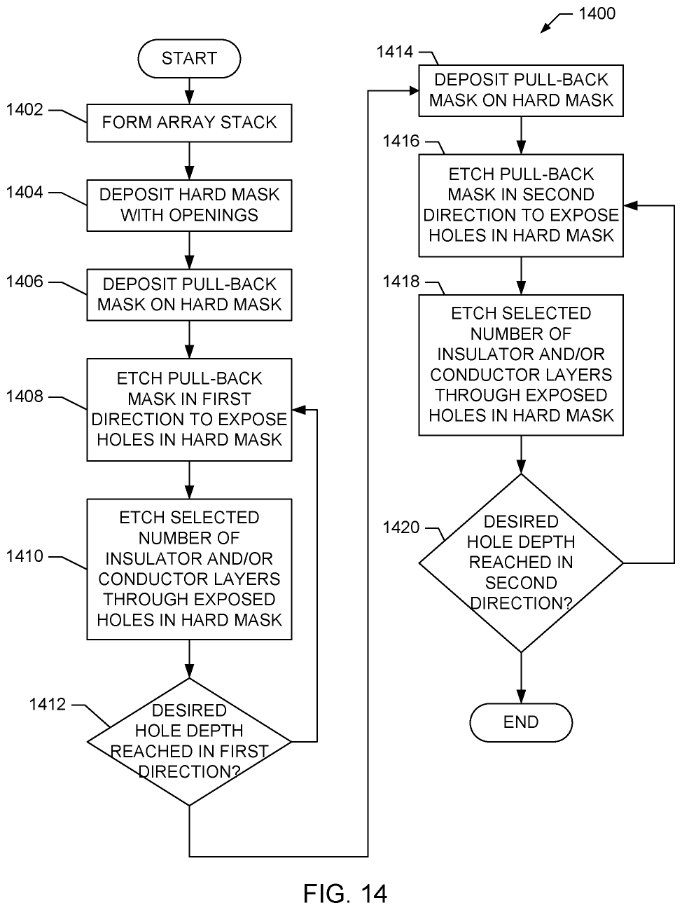

FIG. 14 shows an exemplary method 1400 for forming a 3D array having aligned deep-trench vertical contacts. For example, the method 1400 is suitable to forms the arrays as described herein.

At block 1402, a 3D array stack is formed. For example, the 3D array stack comprises alternating conductor 101 and insulator 102 layers as illustrated in FIG. 3A.

At block 1404, a hard mask is deposited on top of the 3D array stack. For example, the hard mask 103 is deposited on the 3D array stack as illustrated in FIG. 3A. The hard mask precisely defines one or more holes or openings having any desired size, shape, and pattern. The hard mask has an etching material selectivity that is different from the conductor and insulator layers so that it is possible to etch the conductor and insulator layers through the openings in the hard mask without etching the hard mask itself.

At block 1406, a first pull-back mask is deposited on the hard mask. For example, the pull-back mask 105 is deposited on the hard mask 103 as illustrated in FIG. 3B.

At block 1408, the pull-back mask is etched in a particular direction to expose one or more holes or openings in the hard mask. For example, the pull-back mask 105 is etched in the first direction 304a to expose the holes 301a-c in the hard mask 103 as illustrated in FIG. 3B.

At block 1410, a selected number or insulator and/or conductor layers are etched through the exposed openings in the hard mask. For example, as illustrated in FIG. 3B, three conductor layers and three insulators layers are etched through the exposed openings in the hard mask 103. In various embodiments, any number or conductor and/or insulator layers may be etched through an exposed opening in the hard mask.

At block 1412, a determination is made as to whether the desired hole depths associated with the openings in the hard mask have been reached while etching the hard mask in the first direction. If the desired hole depths are reached, the method proceeds to block 1414. If the desired hole depths are not reached, the method proceeds to block 1408 where the pull-back mask is again etched in the first direction 304a to expose more holes in the hard mask 105 and etching of the conductor and insulator layers can be performed.

At block 1414, a second pull-back mask is deposited on the hard mask. For example, the pull-back mask 106 is deposited on the hard mask 103 as illustrated in FIG. 3H

At block 1408, the pull-back mask is etched in a particular direction to expose one or more holes or openings in the hard mask. For example, the pull-back mask 106 is etched in the second direction 304e to expose the holes 301a, 302a, and 303a in the hard mask 103 as illustrated in FIG. 3H.

At block 1410, a selected number or insulator and/or conductor layers are etched through the exposed openings in the hard mask. For example, as illustrated in FIG. 3H, three conductor layers and three insulators layers are etched through the exposed openings in the hard mask 103. In various embodiments, any number or conductor and/or insulator layers may be etched through an exposed opening in the hard mask.

At block 1412, a determination is made as to whether the desired hole depths associated with the openings in the hard mask have been reached while etching the hard mask in the second direction 304e. If the desired hole depths are reached, the method ends. If the desired hole depths are not reached, the method proceeds to block 1416 where the pull-back mask 106 is again etched in the second direction 304e to expose more holes in the hard mask and etching of the conductor and insulator layers can be performed.

Thus, the method 1400 operates to form a 3D array with precisely aligned deep trench contacts. It should be noted that the operation of the method 1400 may be modified, rearranged, deleted, added to, or otherwise changed within the scope of the embodiments.

While exemplary embodiments of the present invention have been shown and described, it will be obvious to those with ordinary skills in the art that based upon the teachings herein, changes and modifications may be made without departing from the exemplary embodiments and their broader aspects. Therefore, the appended claims are intended to encompass within their scope all such changes and modifications as are within the true spirit and scope of the exemplary embodiments of the present invention.

What is claimed is:

1. A method comprising:
forming an array stack having conductor layers and insulator layers;
forming a hard mask on top of the array stack, wherein the hard mask includes a plurality of holes;
forming a pull-back mask on top of the hard mask;
etching the pull-back mask so that at least one hole of the hard mask is exposed; and
etching through one or more exposed holes of the hard mask to remove one or more layers of the array stack.

2. The method of claim 1, further comprising:
etching the pull-back mask to expose one or more additional holes of the hard mask; and
etching through at least one exposed hole to remove one or more layers of the array stack.

3. The method of claim 2, further comprising repeating operations of etching the pull-back mask and etching through the at least one exposed hole until selected depths for each hole in the hard mask have been reached.

4. The method of claim 3, wherein the operation of etching the pull-back mask comprises etching the pull-back mask in a first direction.

5. The method of claim 4, further comprising forming a second pull-back mask on top of the hard mask.

6. The method of claim 5, further comprising:
etching the second pull-back mask to expose one or more additional holes; and
etching through at least one exposed hole to remove one or more layers of the array stack.

7. The method of claim 6, further comprising repeating operations of etching the second pull-back mask and etching through the at least one exposed hole until selected depths for each hole in the hard mask have been reached.

8. The method of claim 7, wherein the operation of etching the second pull-back mask comprises etching the second pull-back mask in a second direction that is different from the first direction.

9. The method of claim 8, wherein the selected depth for each hole results in each hole providing an aligned contact hole through the array stack to an associated conductor layer.

10. The method of claim 8, further comprising filling each hole with contact material to form a conductive path from an associated conductor layer to the top surface of the array stack.

11. The method of claim 1, wherein the operation of forming a hard mask comprises forming the hard mask to have the plurality of holes, wherein the plurality of holes form any desired pattern, and wherein each hole has a shape that is one of circular, square, rectangular, triangular, oval, pentagonal, or hexagonal.

12. A three-dimensional (3D) array formed by performing operations comprising:
forming an array stack having conductor layers and insulator layers;
forming a hard mask on top of the array stack, wherein the hard mask includes a plurality of holes;
forming a pull-back mask on top of the hard mask;
etching the pull-back mask so that at least one hole of the hard mask is exposed; and
etching through one or more exposed holes of the hard mask to remove one or more layers of the array stack.

13. The 3D array of claim 12, wherein the array is formed by performing operations comprising:
etching the pull-back mask to expose one or more additional holes of the hard mask; and
etching through at least one exposed hole to remove one or more layers of the array stack.

14. The 3D array of claim 13, wherein the array is formed by repeating the operations of etching the pull-back mask and etching through the at least one exposed hole until selected depths for each hole in the hard mask have been reached.

15. The 3D array of claim 14, wherein the array is formed by etching the pull-back mask in a first direction.

16. The 3D array of claim 15, wherein the array is formed by forming a second pull-back mask on top of the hard mask.

17. The 3D array of claim 16, wherein the array is formed by:
etching the second pull-back mask to expose one or more additional holes; and
etching through at least one exposed hole to remove one or more layers of the array stack.

18. The 3D array of claim 17, wherein the array is formed by repeating operations of etching the second pull-back mask and etching through the at least one exposed hole until selected depths for each hole in the hard mask have been reached.

19. The 3D array of claim 18, wherein the array is formed by etching the second pull-back mask in a second direction that is different from the first direction.

20. The 3D array of claim 18, wherein the selected depth for each hole results in each hole providing an aligned contact hole through the array stack to an associated conductor layer.
